(19) United States
(12) Patent Application Publication
(10) Pub. No.: US 2026/0105937 A1
(43) Pub. Date: Apr. 16, 2026

(54) SRAM CIRCUIT WITH CFET DEVICES

(71) Applicant: TAIWAN SEMICONDUCTOR MANUFACTURING COMPANY, LTD., Hsinchu (TW)

(72) Inventors: Ping-Wei WANG, Hsinchu (TW); Jui-Lin CHEN, Hsinchu (TW); Kian-Long LIM, Hsinchu (TW)

(21) Appl. No.: 19/052,576

(22) Filed: Feb. 13, 2025

Related U.S. Application Data
(60) Provisional application No. 63/707,605, filed on Oct. 15, 2024.

(51) Int. Cl. G11C 5/06; H10D 30/00; H10D 30/01; H10D 30/43; H10D 62/10; H10D 84/01; H10D 84/85

(52) U.S. Cl. CPC G11C 5/063; H10D 30/014; H10D 30/0191; H10D 30/43; H10D 30/502; H10D 62/121; H10D 84/0186; H10D 84/851

(57) ABSTRACT

An integrated circuit device includes a pair of stacked active-region structures extending in a first direction. The integrated circuit also includes a first switching gate-conductor, a first CFET gate-conductor, a second CFET gate-conductor, and a second switching gate-conductor intersecting the pair of stacked active-region structures and aligned correspondingly with a first gate track, a second gate track, a third gate track, and a fourth gate track extending in a second direction. A first CFET terminal-conductor extending in the second direction between the first gate track and the second gate track is conductively connected to the second CFET gate-conductor. A second CFET terminal-conductor extending in the second direction between the third gate track and the fourth gate track is conductively connected to the first CFET gate-conductor.

### PRIORITY CLAIM

The present application claims the priority of U.S. Provisional Application No. 63/707,605, filed Oct. 15, 2024, which is incorporated herein by reference in its entirety.

### BACKGROUND

An integrated circuit (IC) typically includes a number of IC devices that are manufactured in accordance with one or more IC layout diagrams. IC devices sometimes include complementary field effect transistor devices (“CFET devices”). A CFET device generally has an upper FET overlying a lower FET in a stacked configuration. Both the upper FET and the lower FET in a CFET device are positioned above the conductive lines in a lower conducting layer but below the conductive lines in an upper conducting layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a layout diagram of an integrated circuit having static random-access memory circuits implemented with CFET devices in a circuit cell, in accordance with some embodiments.

FIG. 1B is a schematic of the integrated circuit in FIG. 1A labeled with various elements, in accordance with some embodiments. FIG. 1C is a circuit diagram depicting the SRAM bit-cell circuits in FIGS. 1A-1B.

FIGS. 2A-2C are cross-sectional views of the integrated circuit in FIG. 1A along various cutting planes, in accordance with some embodiments.

FIG. 3A is a layout diagram of an integrated circuit which has layout patterns specifying additional elements in layers either above or below the elements already displayed in FIG. 1A, in accordance with some embodiments.

FIG. 3B is a layout diagram of an integrated circuit which has layout patterns specifying additional elements in a layer above the elements already displayed in FIG. 3A and FIG. 1A, in accordance with some embodiments.

FIG. 4 is a cross-sectional view of the integrated circuit along the cutting plane C-C′ in FIG. 1A, in accordance with some embodiments.

FIG. 5A is a layout diagram of an integrated circuit having static random-access memory circuits implemented with CFET devices in a circuit cell, in accordance with some embodiments.

FIG. 5B is a layout diagram of an integrated circuit which has layout patterns specifying additional elements in layers either above or below the elements already displayed in FIG. 5A, in accordance with some embodiments.

FIGS. 6A-6B are example variations of the layout arrangements in FIG. 5B, in accordance with some embodiments.

FIGS. 7A-7B are correspondingly the upper portion and the lower portion of a layout diagram of a circuit cell 700 which has four SRAM circuits implemented with CFET devices, in accordance with some embodiments. FIG. 7C is a circuit diagram depicting the SRAM bit-cell circuits in FIGS. 7A-7B.

FIG. 8 is the upper portion of a layout diagram of a circuit cell which has four SRAM circuits implemented with CFET devices, in accordance with some embodiments.

FIG. 9 is a schematic of some portions of a matrix of circuit cells, in accordance with some embodiments.

FIG. 10 is a flowchart of a method of manufacturing an integrated circuit (IC) having CFET devices, in accordance with some embodiments.

FIG. 11 is a block diagram of an electronic design automation (EDA) system in accordance with some embodiments.

FIG. 12 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a static random-access memory (“SRAM”) bit-cell circuit with CFET devices (“complementary field effect transistor” devices) is implemented based on a pair of stacked active-region structures. The pair of stacked active-region structures includes an upper active-region structure and a lower active-region structure stacked with each other along a direction perpendicular to a substrate. Each CFET device includes a PMOS transistor and an NMOS transistor stacked with each other on the substrate. The SRAM bit-cell circuit includes a first switching transistor, a first CFET device, a second CFET device, and a second switching transistor.

The pair of stacked active-region structures extending in an X-direction and passing across four gate tracks each extending in a Y-direction. The four gate tracks are distributed evenly along the X-direction in an order of a first gate track, a second gate track, a third gate track, and a fourth gate track. A gate-conductor of the first switching transistor, a gate-conductor of a first CFET gate-conductor, a gate-conductor of a second CFET gate-conductor, and a gate-conductor of a second switching gate-conductor are aligned correspondingly with the first gate track, the second gate track, the third gate track, and the fourth gate track. A joint drain terminal of the first CFET device extending in the Y-direction is between the first gate track and the second gate track. A joint drain terminal of the second CFET device extending in the Y-direction is between the third gate track and the fourth gate track. A first node-connector extending in the first direction conductively connects the joint drain terminal of the first CFET device with the gate-conductor of the first CFET gate-conductor. A second node-connector extending in the first direction conductively connects the joint drain terminal of the second CFET device with the gate-conductor of the first CFET gate-conductor.

A first bit-line conductor is coupled to a first node in the SRAM bit-cell circuit through the channel of the first switching transistor, and a second bit-line conductor is coupled to a second node in the SRAM bit-cell circuit through the channel of the second switching transistor. In some embodiments, based on the present disclosed layout design of the SRAM bit-cell circuit, the current carry capability of bit-line conductors for writing a bit value into the SRAM bit-cell circuit or for reading a bit value from the SRAM bit-cell circuit is improved, as compared with some existing layout designs. In some embodiments, spurious capacitive coupling between the first bit-line conductor and the second bit-line conductor is also reduced.

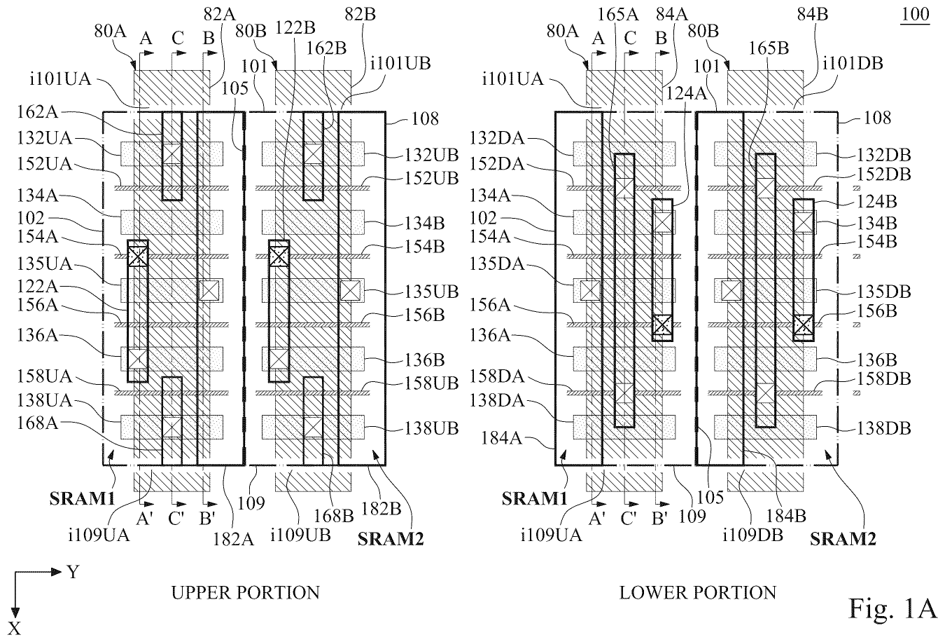

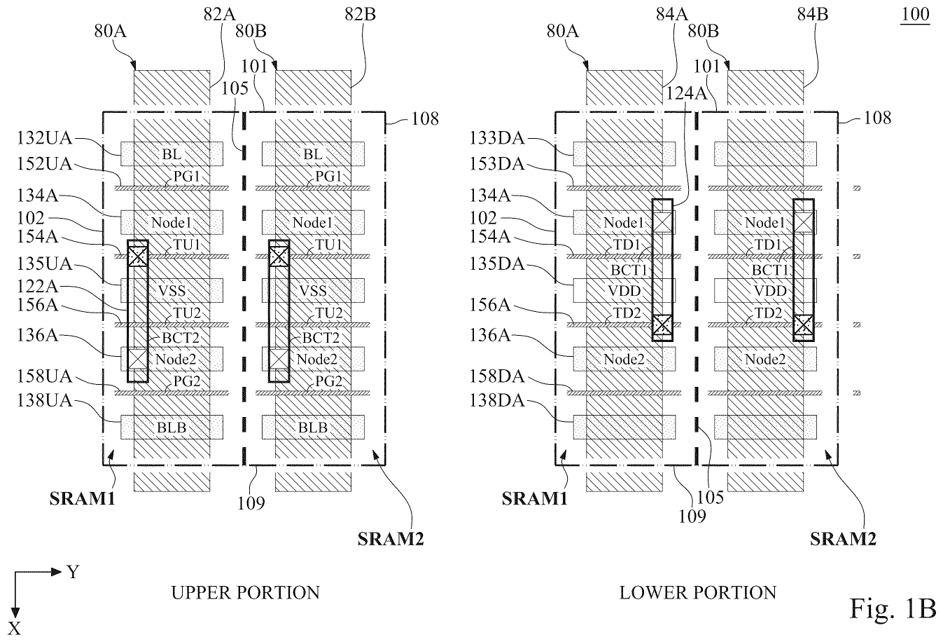

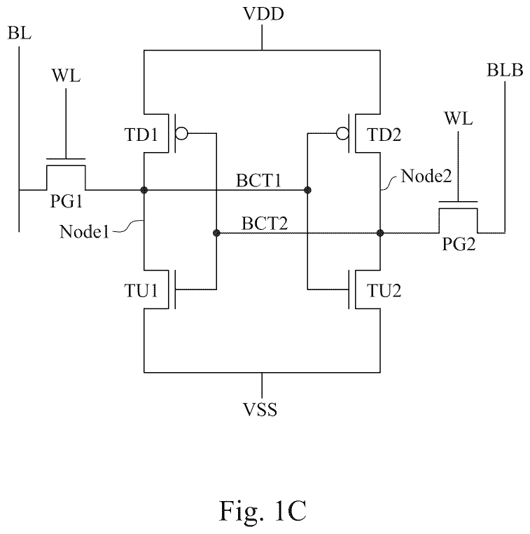

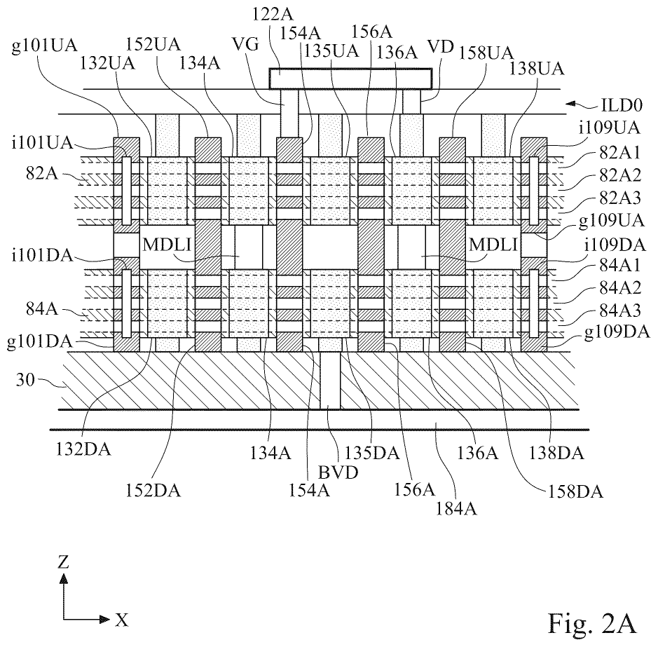

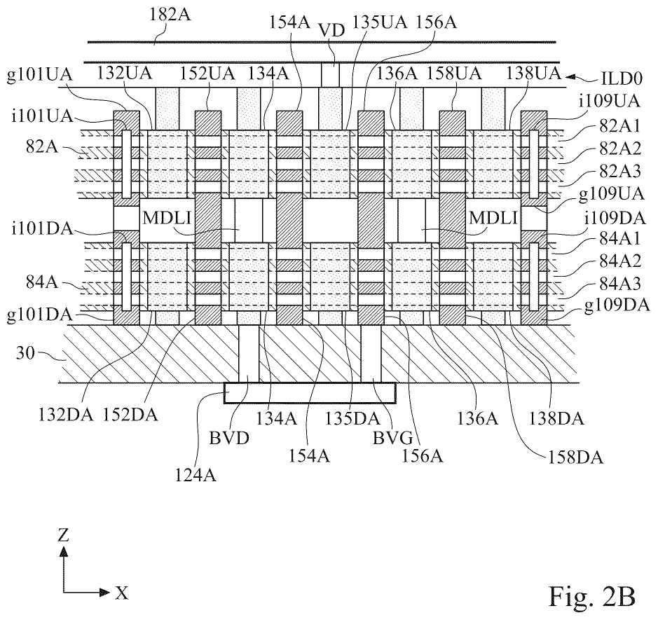

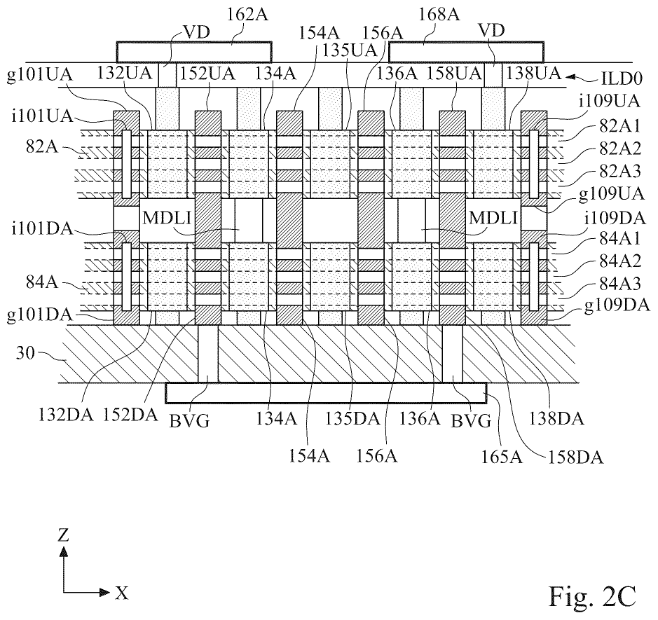

FIG. 1A is a layout diagram of an integrated circuit having SRAM bit-cell circuits implemented with CFET devices in a circuit cell, in accordance with some embodiments. FIG. 1B is a schematic of the integrated circuit in FIG. 1A labeled with various elements, in accordance with some embodiments. The integrated circuit in FIGS. 1A-1B has a circuit cell 100 which has cell boundaries 101 and 109 extending in the Y-direction and cell boundaries 102 and 108 extending in the X-direction. A dividing boundary 105 divides the circuit cell 100 into two parts. The circuit cell 100 is implemented with two SRAM bit-cell circuits. A first SRAM bit-cell circuit SRAM1 is implemented in a first part of the circuit cell 100 between the cell boundary 102 and the dividing boundary 105. A second SRAM bit-cell circuit SRAM2 is implemented in a second part of the circuit cell 100 between the dividing boundary 105 and the cell boundary 108. The first SRAM bit-cell circuit SRAM1 is implemented with transistors in a first pair of stacked active-region structures 80A. The second SRAM bit-cell circuit SRAM2 is implemented with transistors in a second pair of stacked active-region structures 80B. A cross-sectional view of the stacked active-region structures is shown in each of FIGS. 2A-2C.

FIGS. 2A-2C are cross-sectional views of the integrated circuit in FIG. 1A along various cutting planes, in accordance with some embodiments. Specifically, the cross-sectional views of the integrated circuit along the cutting planes as specified by the lines A-A′, B-B′, and C-C′ in FIG. 1A are correspondingly depicted in FIG. 2A, FIG. 2B, and FIG. 2C.

In FIGS. 1A-1B and FIGS. 2A-2C, the first pair of stacked active-region structures 80A extending in the X-direction includes an upper active-region structure 82A and a lower active-region structure 84A stacked with each other along the Z-direction, and the lower active-region structure 84A is between the upper active-region structure 82A and the substrate 30. The second pair of stacked active-region structures 80B extending in the X-direction includes an upper active-region structure 82B and a lower active-region structure 84B stacked with each other along the Z-direction, and the lower active-region structure 84B is between the upper active-region structure 82A and the substrate 30. Here, the Z-direction is a normal direction of the substrate 30.

Each of the upper active-region structures 82A and 82B contains channel regions and source/drain regions of first-type transistors, and each of the lower active-region structures 84A and 84B contains channel regions and source/drain regions of second-type transistors. In some implementation, the first-type transistors are PMOS transistors while the second-type transistors are NMOS transistors. In some implementation, the first-type transistors are NMOS transistors while the second-type transistors are PMOS transistors. In some embodiments, each of the upper active-region structures 82A and 82B and each of the lower active-region structures 84A and 84B include one or more nano-sheets, and consequently, each of the PMOS transistor and the NMOS transistor in FIG. 1A is a nano-sheet transistor. In some embodiments, each of the upper active-region structures 82A and 82B and each of the lower active-region structures 84A and 84B include one or more nano-wires, and consequently, each of the PMOS transistor and the NMOS transistor in FIG. 1A is a nano-wire transistor.

In FIGS. 1A-1B and FIGS. 2A-2C, each of the first pair of stacked active-region structures 80A and the second pair of stacked active-region structures 80B is implemented to support two or more CFET devices. Each of the CFET devices includes a PMOS transistor and an NMOS transistor stacked with each other on the substrate 30.

The layout diagram in FIG. 1A includes an upper portion of the layout and a lower portion of the layout. Various gate-conductors and various terminal-conductors intersecting the upper active-region structures 82A and 82B are shown in the upper portion of the layout. Various gate-conductors and various terminal-conductors intersecting the lower active-region structures 84A and 84B are shown in the lower portion of the layout.

As shown in the upper portion of the layout, four gate-conductors 152UA, 154A, 156A, and 158UA intersect the upper active-region structure 82A in the first pair of stacked active-region structures 80A, and four gate-conductors 152UB, 154B, 156B, and 158UB intersect the upper active-region structure 82B in the second pair of stacked active-region structures 80B. Each of the four gate-conductors 152UA, 154A, 156A, and 158UA is aligned with a gate track extending in the Y-direction. Each of the four gate-conductors 152UB, 154B, 156B, and 158UB is also aligned with a gate track extending in the Y-direction. A gate track specifies a permissible position where a gate-conductor is allowed to be placed. In FIG. 1A, four gate tracks extending in the Y-direction are distributed evenly along the X-direction. The gate-conductors 152UA and 152UB are aligned with a first gate track, the gate-conductors 154A and 154B are aligned with a second gate track, the gate-conductors 156A and 156B are aligned with a third gate track, and the gate-conductors 158UA and 158UB are aligned with a fourth gate track. The pitch distance between two adjacent gate-conductors is one contact poly pitch (“CPP”), which is also the separation distance between two adjacent gate tracks.

As shown in the lower portion of the layout, four gate-conductors 152DA, 154A, 156A, and 158DA intersect the lower active-region structure 84A in the first pair of stacked active-region structures 80A, and four gate-conductors 152DB, 154B, 156B, and 158DB intersect the lower active-region structure 84B in the second pair of stacked active-region structures 80B. Each of the four gate-conductors 152DA, 154A, 156A, and 158DA is aligned with one of the four gate tracks extending in the Y-direction. Each of the four gate-conductors 152DB, 154B, 156B, and 158DB is also aligned with one of the four gate tracks extending in the Y-direction. Specifically, the gate-conductors 152DA and 152DB are aligned with the first gate track, the gate-conductors 154A and 154B are aligned with the second gate track, the gate-conductors 156A and 156B are aligned with the third gate track, and the gate-conductors 158DA and 158DB are aligned with the fourth gate track.

The upper portion of the layout also includes the layout patterns for specifying terminal-conductors 132UA, 134A, 135UA, 136A, and 138UA extending in the Y-direction, the layout patterns for specifying terminal-conductors 132UB, 134B, 135UB, 136B, and 138UB extending in the Y-direction. The integrated circuit in FIG. 1A includes an upper conducting layer which is above the upper active-region structures (i.e., 82A and 82B). The upper portion of the layout in FIG. 1A includes the layout patterns for specifying node-connectors 122A and 122B extending in the X-direction in the upper conducting layer, the layout patterns for specifying bit-line conductors 162A, 168A, 162B, and 168B extending in the X-direction in the upper conducting layer, and the layout patterns for specifying power-line conductors 182A and 182B extending in the X-direction in the upper conducting layer.

The lower portion of the layout also includes the layout patterns for specifying terminal-conductors 132DA, 134A, 135DA, 136A, and 138DA extending in the Y-direction, the layout patterns for specifying terminal-conductors 132DB, 134B, 135DB, 136B, and 138DB extending in the Y-direction. The integrated circuit in FIG. 1A includes a lower conducting layer which is below the lower active-region structures (i.e., 84A and 84B). The lower portion of the layout in FIG. 1A includes the layout patterns for specifying node-connectors 124A and 124B extending in the X-direction in the lower conducting layer, the layout patterns for specifying switch-select conductors 165A and 165B extending in the X-direction in the lower conducting layer, and the layout patterns for specifying power-line conductors 184A and 184B extending in the X-direction in the lower conducting layer.

As shown in FIGS. 1A-1B, the first SRAM bit-cell circuit SRAM1 is implemented with various elements in a first part of the circuit cell 100 between the cell boundary 102 and the dividing boundary 105, while the second SRAM bit-cell circuit SRAM2 is implemented in a second part of the circuit cell 100 between the dividing boundary 105 and the cell boundary 108. Each of the first SRAM bit-cell circuit SRAM1 and the second SRAM bit-cell circuit SRAM2 is implemented with two first-type transistors TU1 and TU2, two second-type transistors TD1 and TD2, and two switching transistors PG1 and PG2. Because the implementation of the first SRAM bit-cell circuit SRAM1 and the implementation of the second SRAM bit-cell circuit SRAM2 are similar, the implementation of the first SRAM bit-cell circuit SRAM1 is described in more detail with reference to FIGS. 1A-1B and FIGS. 2A-2C.

As shown in FIGS. 1A-1B, the first SRAM bit-cell circuit SRAM1 is implemented with transistors in the first pair of stacked active-region structures 80A. In FIG. 1A, the gate-conductor 154A (which is a CFET gate-conductor) intersects the first pair of stacked active-region structures 80A as a joined gate of a first CFET device CFET1. That is, an upper gate-conductor in the gate-conductor 154A intersects the upper active-region structure 82A at a channel region of a first-type transistor TU1, and a lower gate-conductor in the gate-conductor 154A intersects the lower active-region structure 84A at a channel region of a second-type transistor TD1. The upper gate-conductor and the lower gate-conductor in the gate-conductor 154A are conductively connected together. The first-type transistor TU1 and the second-type transistor TD1 are stacked with each other and form the first CFET device CFET1.

In addition, the terminal-conductor 134A (which is a CFET terminal-conductor) intersects the first pair of stacked active-region structures 80A as a joint drain terminal of the first CFET device CFET1. That is, an upper terminal-conductor in the terminal-conductor 134A intersects the upper active-region structure 82A at a drain region of the first-type transistor TU1 in the first CFET device CFET1, and a lower terminal-conductor in the terminal-conductor 134A intersects the lower active-region structure 84A at a drain region of the second-type transistor TD1 in the first CFET device CFET1. The upper terminal-conductor and the lower terminal-conductor in the terminal-conductor 134A are conductively connected together.

Furthermore, the gate-conductor 152UA (which functions as a switching gate-conductor) intersects the upper active-region structure 82A at a channel region of a first switching transistor PG1. The terminal-conductor 132UA intersects the upper active-region structure 82A at a terminal region (i.e., a source or drain region) of the first switching transistor PG1. The channel of the first switching transistor PG1 is coupled between the terminal-conductor 132UA and the terminal-conductor 134A. The terminal-conductor 132UA (which functions as a first bit-IO terminal-conductor BL) is further connected to the bit-line conductor 162A through a via-connector VD.

In FIG. 1A, the gate-conductor 156A (which is a CFET gate-conductor) intersects the first pair of stacked active-region structures 80A as a joined gate of a second CFET device CFET2. That is, an upper gate-conductor in the gate-conductor 156A intersects the upper active-region structure 82A at a channel region of a first-type transistor TU2, and a lower gate-conductor in the gate-conductor 156A intersects the lower active-region structure 84A at a channel region of a second-type transistor TD2. The upper gate-conductor and the lower gate-conductor in the gate-conductor 156A are conductively connected together. The first-type transistor TU2 and the second-type transistor TD2 are stacked with each other and form the second CFET device CFET2.

In addition, the terminal-conductor 136A (which is a CFET terminal-conductor) intersects the first pair of stacked active-region structures 80A as a joint drain terminal of the second CFET device CFET2. That is, an upper terminal-conductor in the terminal-conductor 136A intersects the upper active-region structure 82A at a drain region of the first-type transistor TU2 in the second CFET device CFET2, and a lower terminal-conductor in the terminal-conductor 136A intersects the lower active-region structure 84A at a drain region of the second-type transistor TD2 in the second CFET device CFET2. The upper terminal-conductor and the lower terminal-conductor in the terminal-conductor 136A are conductively connected together.

Furthermore, the gate-conductor 158UA (which functions as a switching gate-conductor) intersects the upper active-region structure 82A at a channel region of a second switching transistor PG2. The terminal-conductor 138UA intersects the upper active-region structure 82A at a terminal region (i.e., a source or drain region) of the second switching transistor PG2. The channel of the second switching transistor PG2 is coupled between the terminal-conductor 138UA and the terminal-conductor 136A. The terminal-conductor 138UA (which functions as a second bit-IO terminal-conductor BLB) is further connected to the bit-line conductor 168A through a via-connector VD.

In FIG. 1A, the terminal-conductor 135UA (which functions as a first power terminal-conductor) intersects the upper active-region structure 82A at the source regions of the first-type transistors TU1 and TU2. Thus, the terminal-conductor 135UA functions as a source terminal for both the first-type transistor TU1 in the first CFET device CFET1 and the first-type transistor TU2 in the second CFET device CFET2. The terminal-conductor 135UA is further connected to the power-line conductor 182A which is configured to receive a first power supply voltage.

The terminal-conductor 135DA (which functions as a second power terminal-conductor) intersects the lower active-region structure 84A at the source regions of the second-type transistors TD1 and TD2. Thus, the terminal-conductor 138UA functions as a source terminal for both the second-type transistor TD1 in the first CFET device CFET1 and the second-type transistor TD2 in the second CFET device CFET2. The terminal-conductor 135DA is further connected to the power-line conductor 184A which is configured to receive a second power supply voltage.

In FIGS. 1A-1B, each SRAM bit-cell circuit (i.e., SRAM1 or SRAM2) is implemented with the first CFET device CFET1, the second CFET device CFET2, the first switching transistor PG1, and the second switching transistor PG2. The first CFET device CFET1 includes the first-type transistor TU1 and the second-type transistor TD1. The second CFET device CFET2 includes the first-type transistor TU2 and the second-type transistor TD2. The first-type transistors TU1, TU2, PG1, and PG2 are identified in the upper portion of the layout diagram in FIG. 1B. The second-type transistors TD1 and TD2 are identified in the lower portion of the layout diagram in FIG. 1B. The node-connectors 122A and 124A extending in the X-direction for implementing the first SRAM bit-cell circuit SRAM1 are also identified in FIG. 1B. The electric connections of the various elements in the first SRAM bit-cell circuit SRAM1 (or similarly in the second SRAM bit-cell circuit SRAM2) are depicted in the circuit diagram of FIG. 1C.

The node-connector 124A is conductively connected to the terminal-conductor 134A through a via-connector VD and conductively connected to the gate-conductor 156A through a via-connector VG. Consequently, the jointed drain terminal of the first CFET device CFET1 (at the terminal-conductor 134A) and the joined gate of the second CFET device CFET2 (the gate-conductor 156A) are conductively connected together and form a first connection node Node1. For forming the jointed drain terminal of the first CFET device CFET1, the drain terminals of the first-type transistor TU1 and the second-type transistor TD1 are conductively connected together. For forming the joined gate of the second CFET device CFET2, the gates of the first-type transistor TU2 and the second-type transistor TD2 are conductively connected together.

The node-connector 122A is conductively connected to the gate-conductor 154A through a via-connector VG and conductively connected to the terminal-conductor 136A through a via-connector VD. Consequently, the joined gate of the first CFET device CFET1 (at the gate-conductor 154A) and the jointed drain terminal of the second CFET device CFET2 (at the terminal-conductor 136A) are conductively connected together and form a second connection node Node2. For forming the joined gate of the first CFET device CFET1, the gates of the first-type transistor TU1 and the second-type transistor TD1 are conductively connected together. For forming the jointed drain terminal of the second CFET device CFET2, the drain terminals of the first-type transistor TU2 and the second-type transistor TD2 are conductively connected together.

In FIG. 1A, because the bit-line conductor 162A is connected to the terminal-conductor 132UA, the conductive connection between the bit-line conductor 162A and the first connection node Node1 (at the terminal-conductor 134A) is determined by the connection state of the first switching transistor PG1. Thus, a voltage applied to the gate-conductor 152UA controls whether the bit-line conductor 162A is conductively connected to the first connection node Node1 or electrically isolated from the first connection node Node1.

Because the bit-line conductor 168A is connected to the terminal-conductor 138UA, the conductive connection between the bit-line conductor 168A and the second connection node Node2 (at the terminal-conductor 136A) is determined by the connection state of the second switching transistor PG2. Thus, a voltage applied to the gate-conductor 158UA controls whether the bit-line conductor 168A is conductively connected to the second connection node Node2 or electrically isolated from the second connection node Node2.

In FIG. 1A, the switch-select conductor 165A is conductively connected to each of the gate-conductor 152DA and the gate-conductor 158DA through a corresponding via-connector BVG. The gate-conductor 152DA and the gate-conductor 158DA intersecting the lower active-region structure 84A are correspondingly connected to the gate-conductor 152UA and the gate-conductor 158UA intersecting the upper active-region structure 82A. Thus, a voltage applied to the switch-select conductor 165A controls whether the connection nodes Node1 and Node2 are correspondingly connected to the bit-line conductor 162A and 168A for reading or writing the bit value stored in the first SRAM bit-cell circuit SRAM1 (which is implemented with the first pair of stacked active-region structures 80A).

In some embodiments, the first-type transistors TU1 and TU2 in the upper active-region structure 82A are NMOS transistors, while the second-type transistors TD1 and TD2 in the lower active-region structure 84A are PMOS transistors. The power-line conductor 182A in the upper conducting layer is configured to be maintained at a lower supply voltage VSS, while the power-line conductor 184A in the lower conducting layer is configured to be maintained at an upper supply voltage VDD. The equivalent circuit of the first SRAM bit-cell circuit SRAM1 implemented with the first pair of stacked active-region structures 80A is shown in FIG. 1C. The node-connector 124A and the node-connector 122A are correspondingly labeled as BCT1 and BCT2, in FIG. 1C and also in FIG. 1B.

In some alternative embodiments, the first-type transistors TU1 and TU2 in the upper active-region structure 82A are PMOS transistors, while the second-type transistors TD1 and TD2 in the lower active-region structure 84A are NMOS transistors. The power-line conductor 182A in the upper conducting layer is configured to be maintained at an upper supply voltage VDD, while the power-line conductor 184A in the lower conducting layer is configured to be maintained at a lower supply voltage VSS. People skilled in the art understand that the equivalent circuit of the first SRAM bit-cell circuit SRAM1 for the alternative embodiments is a modification of the equivalent circuit in FIG. 1C.

Some of the elements for implementing the first SRAM bit-cell circuit SRAM1 in the first pair of stacked active-region structures 80A of FIG. 1A and the interconnects between some of the elements are also depicted in the cross-sectional views in FIGS. 2A-2C.

FIGS. 2A-2C are cross-sectional views of the integrated circuit of FIG. 1A correspondingly along the cutting plane A-A′, B-B′, and C-C′, in accordance with some embodiments. The CFET gate-conductor of the first CFET device CFET1 is the gate-conductor 154A. The upper gate-conductor and the lower gate-conductor in the gate-conductor 154A correspondingly intersect the upper active-region structure 82A and the lower active-region structure 84A at a corresponding channel region of the first-type transistor TU1 or the second-type transistor TD1. The upper gate-conductor and the lower gate-conductor in the gate-conductor 154A are conductively connected together.

In FIGS. 2A-2C, the CFET gate-conductor of the second CFET device CFET2 is the gate-conductor 156A. The upper gate-conductor and the lower gate-conductor in the gate-conductor 156A correspondingly intersect the upper active-region structure 82A and the lower active-region structure 84A at a corresponding channel region of the first-type transistor TU2 or the second-type transistor TD2. The upper gate-conductor and the lower gate-conductor in the gate-conductor 156A are conductively connected together.

In FIGS. 2A-2C, the switching gate-conductor of the first switching transistor PG1 is the gate-conductor 152UA, and the switching gate-conductor of the second switching transistor PG2 is the gate-conductor 158UA.

In FIGS. 2A-2C, the CFET terminal-conductor of the first CFET device CFET1 is the terminal-conductor 134A. The upper terminal-conductor and the lower terminal-conductor in the terminal-conductor 134A correspondingly intersect the upper active-region structure 82A and the lower active-region structure 84A at a corresponding drain region of the first-type transistor TU1 or the second-type transistor TD1. The upper terminal-conductor and the lower terminal-conductor in the terminal-conductor 134A are conductively connected together through a terminal-inter-connector MDLI. The upper terminal-conductor of the terminal-conductor 134A also insects a source/drain region of the first switching transistor PG1 (which has the channel region defined by the gate-conductor 152UA).

In FIGS. 2A-2C, the CFET terminal-conductor of the second CFET device CFET2 is the terminal-conductor 136A. The upper terminal-conductor and the lower terminal-conductor in the terminal-conductor 136A correspondingly intersect the upper active-region structure 82A and the lower active-region structure 84A at a corresponding drain region of the first-type transistor TU2 or the second-type transistor TD2. The upper terminal-conductor and the lower terminal-conductor in the terminal-conductor 136A are conductively connected together through a terminal-inter-connector MDLI. The upper terminal-conductor of the terminal-conductor 136A also insects a source/drain region of the second switching transistor PG2 (which has the channel region defined by the gate-conductor 158UA).

The source terminal for both the first-type transistors TU1 and TU2 is at the terminal-conductor 135UA which intersects the upper active-region structure 82A. The source terminal for both the second-type transistors TD1 and TD2 is at the terminal-conductor 135DA which intersects the lower active-region structure 84A.

In FIG. 2A, the gate-conductor 154A is conductively connected to the node-connector 122A through a via-connector VG, and the terminal-conductor 136A is conductively connected to the node-connector 122A through a via-connector VD. Thus, the node-connector 122A connects the gate-conductor 154A with the terminal-conductor 136A while non-conductively passing across the gate-conductor 156A. In addition, the terminal-conductor 135DA is conductively connected to the power-line conductor 184A through a via-connector BVD.

In FIG. 2B, the terminal-conductor 135UA is conductively connected to the power-line conductor 182A through a via-connector VD. The gate-conductor 156A is conductively connected to the node-connector 124A through a via-connector BVG, and the terminal-conductor 134A is conductively connected to the node-connector 124A through a via-connector BVD. Thus, the node-connector 124A connects the terminal-conductor 134A with the gate-conductor 156A while non-conductively passing across the gate-conductor 154A.

In FIG. 2C, the terminal-conductor 132UA intersects the upper active-region structure 82A at a terminal region (i.e., a source or drain region) of the first switching transistor PG1, and the terminal-conductor 132UA is connected to the bit-line conductor 162A through a via-connector VD. The terminal-conductor 138UA intersects the upper active-region structure 82A at a terminal region (i.e., a source or drain region) of the second switching transistor PG2, and the terminal-conductor 138UA is connected to the bit-line conductor 168A through a via-connector VD. The gate-conductor 152UA is connected to the gate-conductor 152DA which is connected to the switch-select conductor 165A through a via-connector BVG. The gate-conductor 158UA is connected to the gate-conductor 158DA which is connected to the switch-select conductor 165A through a via-connector BVG. Thus, each of the switching gate-conductor for the first switching transistor PG1 and the switching gate-conductor for the second switching transistor PG1 is conductively connected to the switch-select conductor 165A.

In FIG. 2A, the node-connector 122A is in the upper conducting layer, and the power-line conductor 184A is in the lower conducting layer. In FIG. 2B, the power-line conductor 182A in FIG. 2B is in the upper conducting layer, and the node-connector 124A is in the lower conducting layer. In FIG. 2C, each of the bit-line conductor 162A and the bit-line conductor 168A is in the upper conducting layer, and the switch-select conductor 165A is in the lower conducting layer.

In some embodiments, the upper conducting layer is a first frontside metal layer (such as a first metal layer M0) above the upper active-region structure 82A, and each of the via-conductors VD and VG in FIGS. 2A-2C passes through the interlayer dielectric ILD0 between the first frontside metal layer and the upper active-region structures. The lower conducting layer is a first backside metal layer (such as a first backside metal layer BM0) below the lower active-region structure 84A, and each of the via-conductors BVD and BVG in FIGS. 2A-2C passes through the substrate 30. In some alternative embodiments, the lower conducting layer is a buried metal layer between the lower active-region structures (i.e., 84A and 84B) and the substrate 30. Each of the via-conductors BVD and BVG passes through the dielectric between the lower active-region structures (i.e., 84A and 84B) and the buried metal layer.

In some embodiments, each of the active-region structures in FIGS. 2A-2C includes multiple nano-sheets extending in the X-direction. For example, as shown in FIGS. 2A-2C, the upper active-region structure 82A includes nano-sheets 82A1, 82A2, and 82A3 extending in the X-direction, and the lower active-region structure 84A includes nano-sheets 84A1, 84A2, and 84A3 extending in the X-direction. Other implementations of the active-region structures (such as, the implementations with nano-wires) are within the contemplated scope of present disclosure.

In FIGS. 2A-2C, boundary isolation regions i101UA and i109UA are implemented in the upper active-region structure 82A and boundary isolation regions i101DA and i109DA are implemented in the lower active-region structure 84A. Because of the boundary isolation regions i101UA, i109UA, i101DA, and i109DA, the active regions (e.g., channel regions, or source/drain regions) of the transistors in the first SRAM bit-cell circuit SRAM1 are isolated from other active regions outside the circuit cell 100 but in the first pair of stacked active-region structures 80A. Similarly, as shown in FIG. 1A, because of the boundary isolation regions i101UB, i109UB, i101DB, and i109DB, the active regions of the transistors in the second SRAM bit-cell circuit SRAM2 are isolated from other active regions outside the circuit cell 100 but in the second pair of stacked active-region structures 80B.

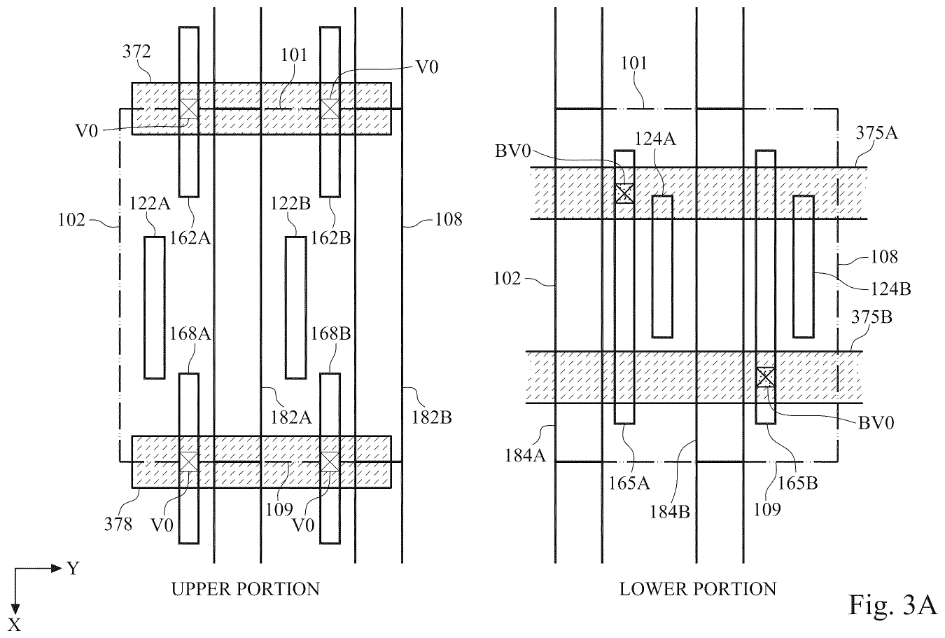

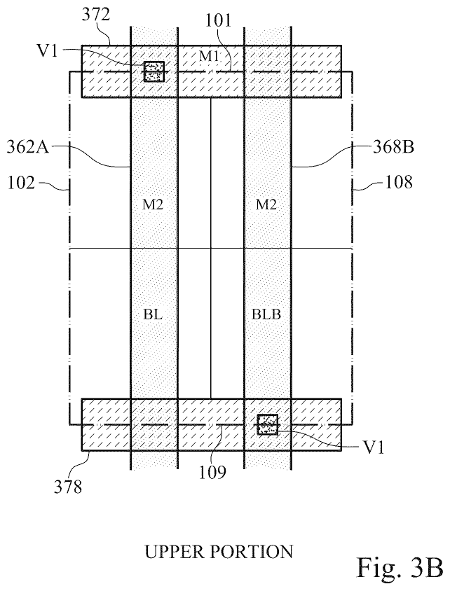

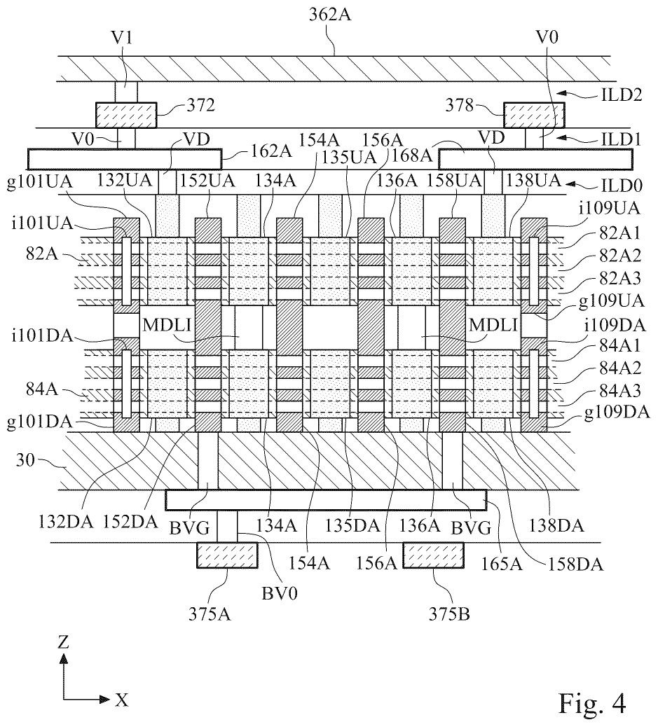

The bit-line conductors (e.g., 162A, 168A, 162B, and 168B) and the switch-select conductors (e.g., 165A and 165B) in the SRAM bit-cell circuits SRAM1 and SRAM2 are connected to various conductors in other conducting layers, as depicted in FIGS. 3A-3B and FIG. 4.

FIG. 3A is a layout diagram of an integrated circuit which has layout patterns specifying additional elements in layers either above or below the elements already displayed in FIG. 1A, in accordance with some embodiments. FIG. 3B is a layout diagram of an integrated circuit which has layout patterns specifying additional elements in a layer above the elements already displayed in FIG. 3A and FIG. 1A, in accordance with some embodiments. FIG. 4 is a cross-sectional view of the integrated circuit along the cutting plane C-C′ in FIG. 1A and includes various elements as specified by FIG. 1A, FIGS. 3A-3B, and FIG. 4, in accordance with some embodiments.

The layout diagram in FIG. 3A includes an upper portion of the layout and a lower portion of the layout. The lower portion of the layout includes layout patterns for specifying the node-connectors 124A and 124B in the lower conducting layer and the switch-select conductors 165A and 165B in the lower conducting layer. In some embodiments, the lower conducting layer which contains the node-connectors and the switch-select conductors extending in the X-direction is a first backside metal layer BM0 (which is below the CFETs in the integrated circuit) at a backside of the substrate. The lower portion of the layout further includes layout patterns for specifying word-lines 375A and 375B extending in the Y-direction in a second backside metal layer BM1 below the first backside metal layer BM0. The switch-select conductor 165A is connected to the word-line 375A in the second backside metal layer BM1 through a via-connector BV0. The switch-select conductor 165B is connected to the word-line 375B in the second backside metal layer BM1 through a via-connector BV0. The via-connector BV0 which connects the switch-select conductor 165A with the word-line 375A is depicted in the cross-sectional view of FIG. 4. The via-connector BV0 passes through the interlayer dielectric between the first backside metal layer BM0 and the second backside metal layer BM1.

In FIG. 3A, the upper portion of the layout includes layout patterns for specifying the node-connectors 122A and 122B in the upper conducting layer and the bit-line conductors 162A, 168A, 162B, and 168B in the upper conducting layer. In some embodiments, the upper conducting layer which contains the node-connectors and the bit-line conductors extending in the X-direction is a first metal layer M0 above the CFETs in the integrated circuit. The upper portion of the layout further includes layout patterns for specifying bit-line interconnect extensions 372 and 378 extending in the Y-direction in a second metal layer M1 above the first metal layer M0. Each of the bit-line conductors 162A and 162B in the first metal layer M0 is connected to the bit-line interconnect extension 372 in the second metal layer M1 through a corresponding via-connector V0. Each of the bit-line conductors 168A and 168B in the first metal layer M0 is connected to the bit-line interconnect extension 378 in the second metal layer M1 through a corresponding via-connector V0.

In addition, as shown in FIG. 3B, each of the bit-line interconnect extensions 372 and 378 in the second metal layer M1 is connected to a corresponding bit-line (i.e., either 362A or 368B) extending in the X-direction in a third metal layer M2 above the second metal layer M1. The bit-line interconnect extensions 372 and 378 are correspondingly connected to the bit-lines 362A and 368B through a corresponding via-connector V1. Consequently, through the bit-line conductors 162A and 162B and the bit-line interconnect extension 372, both the terminal-conductors 132UA and 132UB (in FIG. 1A) are conductively connected to the bit-line 362A. Through the bit-line conductors 168A and 168B and the bit-line interconnect extension 378, both the terminal-conductors 138UA and 138UB (in FIG. 1A) are conductively connected to the bit-line 368B. Each of the terminal-conductors 132UA and 132UB functions as a first bit-IO terminal-conductor BL for a corresponding SRAM bit-cell circuit (i.e., either SRAM1 or SRAM2). Each of the terminal-conductors 138UA and 138UB functions as a second bit-IO terminal-conductor BLB for a corresponding SRAM bit-cell circuit (i.e., either SRAM1 or SRAM2).

The conductive connection from the terminal-conductor 132UA to the bit-line 362A is depicted in the cross-sectional view of FIG. 4. The via-connector VD between the terminal-conductor 132UA and the bit-line conductor 162A passes through the interlayer dielectric ILD0 below the first metal layer M0. The via-connector V0 between the bit-line conductor 162A and the bit-line interconnect extensions 372 passes through the interlayer dielectric ILD1 between the first metal layer M0 and the second metal layer M1. The via-connector V1 between the bit-line interconnect extensions 372 and the bit-line 362A passes through the interlayer dielectric ILD2 between the second metal layer M1 and the third metal layer M2.

The conductive connection from the terminal-conductor 138UA to the bit-line interconnect extension 378 is also depicted in the cross-sectional view of FIG. 4. The via-connector VD between the terminal-conductor 138UA and the bit-line conductor 168A passes through the interlayer dielectric ILD0 below the first metal layer M0. The via-connector V0 between the bit-line conductor 168A and the bit-line interconnect extensions 378 passes through the interlayer dielectric ILD1 between the first metal layer M0 and the second metal layer M1.

In FIG. 3A, each of the bit-line conductors 162A and 162B in the circuit cell 100 extends across the cell boundary 101 and merges with a corresponding bit-line conductor in an adjacent circuit cell. The bit-line interconnect extension 372, which is at the cell boundary 101, overlaps with the two circuit cells bordered with each other at the cell boundary 101. Each of the bit-line conductors 168A and 168B in the circuit cell 100 extends across the cell boundary 109 and merges with a corresponding bit-line conductor in an adjacent circuit cell. The bit-line interconnect extension 378, which is at the cell boundary 109, overlaps with the two circuit cells bordered with each other at the cell boundary 109. In addition, each power-line conductors 182A and 182B extends in the X-direction and passes across both cell boundaries 101 and 109.

In some alternative embodiments, each of the bit-line conductors 162A and 162B in the circuit cell 100 does not extend across the cell boundary 101. In some alternative embodiments, the bit-line interconnect extension 372 does not overlap with the adjacent circuit cell sharing the cell boundary 101 with the circuit cell 100. In some alternative embodiments, each of the bit-line conductors 168A and 168B in the circuit cell 100 does not extend across the cell boundary 109. In some alternative embodiments, The bit-line interconnect extension 378 does not overlap with the adjacent circuit cell sharing the cell boundary 109 with the circuit cell 100.

In the embodiments as shown in FIG. 1A, each of the SRAM bit-cell circuit SRAM1 and SRAM2 in the circuit cell 100 includes a first node-connector (e.g., 122A or 122B) in the upper conducting layer and a second node-connector (e.g., 124A or 124B) in the lower conducting layer. In some alternative embodiments, each of the SRAM bit-cell circuit SRAM1 and SRAM2 in a circuit cell includes two node-connectors (implemented to function as the node-connectors BCT1 and BCT2 in FIG. 1C) in the upper conducting layer. In some alternative embodiments, each of the SRAM bit-cell circuit SRAM1 and SRAM2 in a circuit cell includes two node-connectors (implemented to function as the node-connectors BCT1 and BCT2 in FIG. 1C) in the lower conducting layer.

In the embodiments as shown in FIG. 1A, the terminal-conductor 135UA and the terminal-conductor 135UB are separated in the Y-direction by a gap, even if each of the terminal-conductor 135UA and the terminal-conductor 135UB is configured to receive a same first supply voltage (such as, a lower supply VSS). In some alternative embodiments, the terminal-conductor 135UA and the terminal-conductor 135UB are joined together in the Y-direction. Similarly, in the embodiments as shown in FIG. 1A, the terminal-conductor 135DA and the terminal-conductor 135DB are separated in the Y-direction by a gap, even if each of the terminal-conductor 135DA and the terminal-conductor 135DB is configured to receive a same second supply voltage (such as, an upper supply VDD). In some alternative embodiments, the terminal-conductor 135DA and the terminal-conductor 135DB are joined together in the Y-direction.

In the embodiments as shown in FIG. 1A, the terminal-conductor 132UA and the terminal-conductor 132UB are separated in the Y-direction by a gap, and the terminal-conductor 138UA and the terminal-conductor 138UB are also separated in the Y-direction by a gap. In some alternative embodiments, the terminal-conductor 132UA and the terminal-conductor 132UB are joined together in the Y-direction. In some alternative embodiments, the terminal-conductor 138UA and the terminal-conductor 138UB are joined together in the Y-direction.

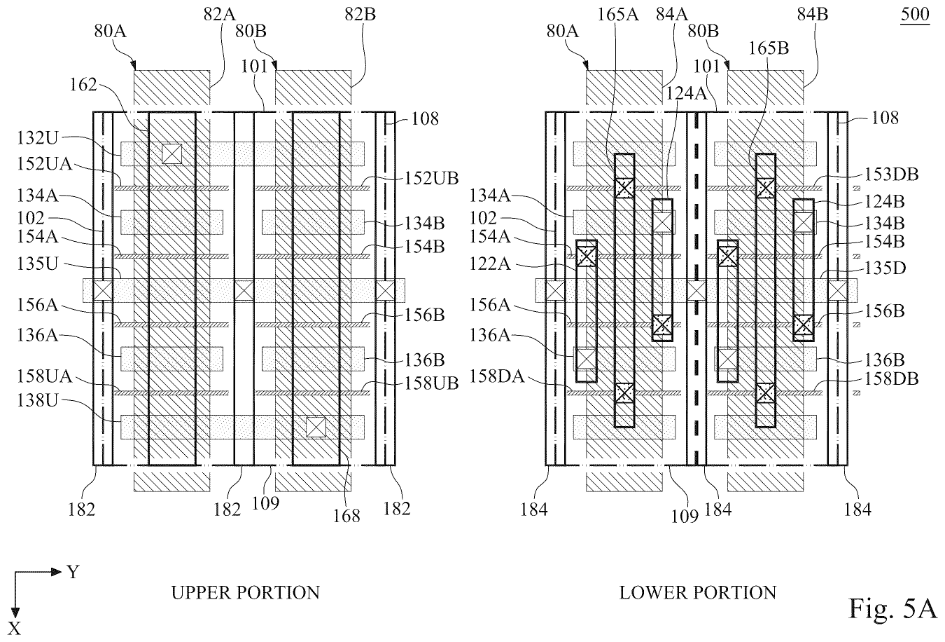

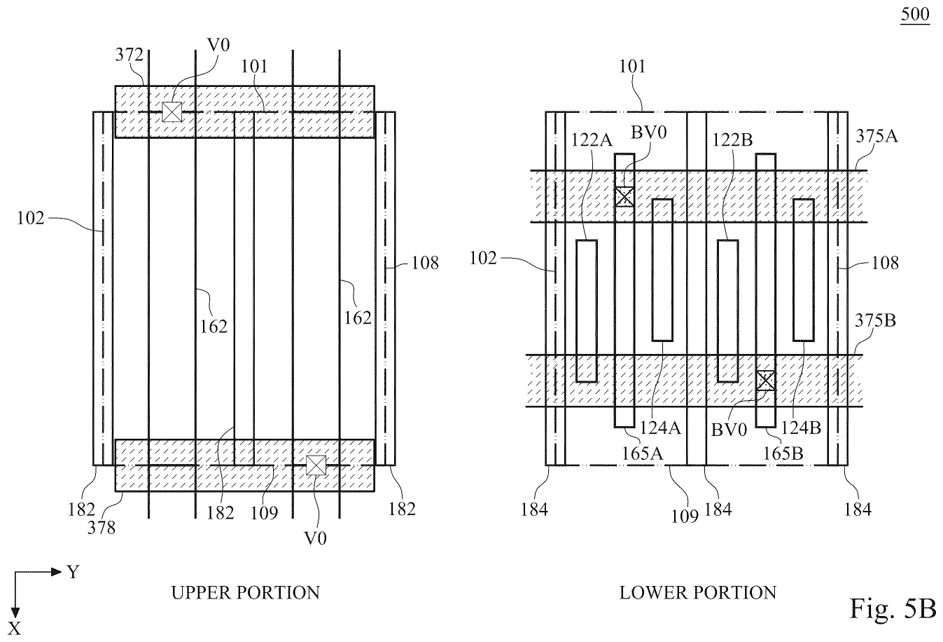

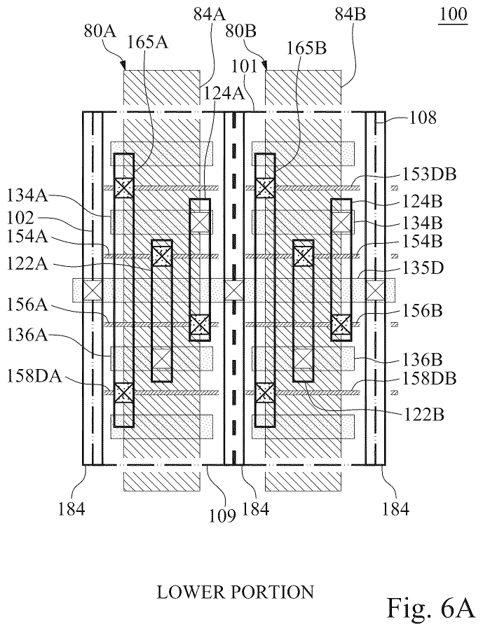

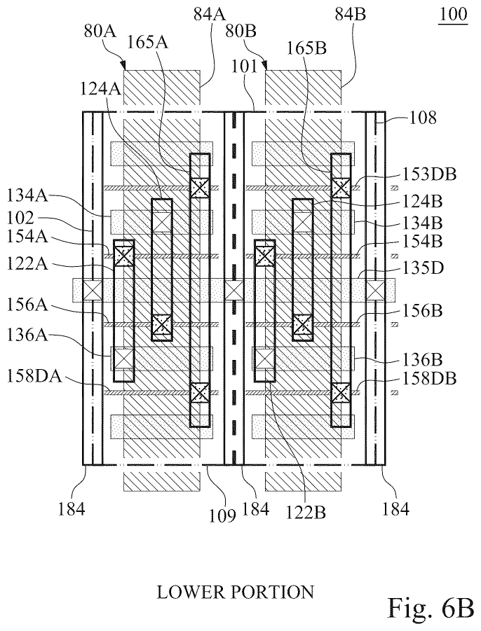

Some implementation variations of the circuit cell 100 of FIGS. 1A-1B are depicted in FIGS. 5A-5B and FIGS. 6A-6B. FIG. 5A is a layout diagram of an integrated circuit having static random-access memory circuits implemented with CFET devices in a circuit cell, in accordance with some embodiments. The circuit cell 500 in FIG. 5A is modified from the circuit cell 100 in FIG. 1A. The terminal-conductor 135UA and the terminal-conductor 135UB in FIG. 1A are joined together as a terminal-conductor 135U in the upper portion of FIG. 5A, and the terminal-conductor 135U intersects both the upper active-region structure 82A and the upper active-region structure 82B. The terminal-conductor 135DA and the terminal-conductor 135DB in FIG. 1A are joined together as a terminal-conductor 135D in the lower portion of FIG. 5A, and the terminal-conductor 135D intersects both the lower active-region structure 84A and the lower active-region structure 84B. In addition, the terminal-conductor 132UA and the terminal-conductor 132UB in FIG. 1A are joined together as a terminal-conductor 132U in the upper portion of FIG. 5A, and the terminal-conductor 132U intersects both the upper active-region structure 82A and the upper active-region structure 82B. The terminal-conductor 138UA and the terminal-conductor 138UB in FIG. 1A are joined together as a terminal-conductor 138U in the upper portion of FIG. 5A, and the terminal-conductor 138U intersects both the upper active-region structure 82A and the upper active-region structure 82B.

Another difference between the circuit cell 500 in FIG. 5A and the circuit cell 100 in FIG. 1A is the implementations of the node-connectors 122A and 122B. In the circuit cell 500 of FIG. 5A, the node-connectors 122A and 122B are implemented in the lower conducting layer. For comparison, in the circuit cell 100 of FIG. 1A, the node-connectors 122A and 122B are implemented in the upper conducting layer. In both FIG. 1A and FIG. 5A, the node-connector 122A is conductively connected between the gate-conductor 154A and the terminal-conductor 136A, and the node-connector 122B is conductively connected between the gate-conductor 154B and the terminal-conductor 136B.

The layout arrangements of the bit-line conductors and power-line conductors in the circuit cell 500 of FIG. 5A are also different from that in the circuit cell 100 of FIG. 1A. In the circuit cell 500, as shown in the upper portion of FIG. 5A, the bit-line conductor 162 extending in the X-direction overlaps with the first pair of stacked active-region structures 80A, and the bit-line conductor 168 extending in the X-direction overlaps with the second pair of stacked active-region structures 80B. The bit-line conductor 162 is conductively connected to the terminal-conductor 132U through a corresponding via-connector VD, and the bit-line conductor 168 is conductively connected to the terminal-conductor 138U through a corresponding via-connector VD, while each of the bit-line conductors 162 and 168 passes across both of the terminal-conductors 132U and 138U.

In the circuit cell 500, as shown in the upper portion of FIG. 5A, two power-line conductors 182 extending in the X-direction are correspondingly positioned at the cell boundaries 101 and 109, and one power-line conductor 184 in the X-direction is positioned between the first pair of stacked active-region structures 80A and the second pair of stacked active-region structures 80B. Each of the three power-line conductors 182 is connected to the terminal-conductor 135U through a corresponding via-connector VD.

In addition, the bit-line conductors 162 and 168 are interleaved with the three power-line conductors 182. Under the condition that one of the three power-line conductors extend in the X-direction parallelly between the bit-line conductors 162 and 168, the power-line conductor between the two bit-line conductors in a same conducting layer provides a signal grounding, which reduces spurious capacitive coupling between the two bit-line conductors. Each of the bit-line conductors 162 and 168 in the circuit cell 500 of FIG. 5A has a wider width than any of the bit-line conductors in the circuit cell 100 of FIG. 1A, as more layout space between the power-lines becomes available for implementing the bit-line conductors 162 and 168 in comparison with what is available in the circuit cell 100.

In the circuit cell 500, as shown in the lower portion of FIG. 5A, two power-line conductors 184 extending in the X-direction are correspondingly positioned at the cell boundaries 101 and 109, and one power-line conductor 184 in the X-direction is positioned between the first pair of stacked active-region structures 80A and the second pair of stacked active-region structures 80B. Each of the three power-line conductors 184 is connected to the terminal-conductor 135D through a corresponding via-connector BVD.

In the circuit cell 500, the connection of the bit-line conductors 162 and 168 to the bit-line interconnect extension in another conducting layer is depicted in the upper portion of FIG. 5B, and the connection of the switch-select conductors 365A and 365B to the word-lines in another conducting layer is depicted in the lower portion of FIG. 5B.

In the upper portion of the layout diagram in FIG. 5B, the bit-line conductor 162 extending in the X-direction in the upper conducting layer (e.g., the first metal layer M0) is connected to the bit-line interconnect extension 372 extending in the Y-direction in another upper conducting layer (e.g., the second metal layer M1) through a corresponding via-connector V0. The bit-line conductor 168 extending in the X-direction in the upper conducting layer (e.g., the first metal layer M0) is connected to the bit-line interconnect extension 378 extending in the Y-direction in another upper conducting layer (e.g., the second metal layer M1) through a corresponding via-connector V0.

In the lower portion of the layout diagram in FIG. 5B, the switch-select conductor 165A extending in the X-direction in the lower conducting layer (e.g., the first backside metal layer BM0) is connected to the word-line 375A extending in the Y-direction in another lower conducting layer (e.g., the second backside metal layer BM1) through a corresponding via-connector BV0. The switch-select conductor 165B extending in the X-direction in the lower conducting layer (e.g., the first metal layer BM1) is connected to the word-line 375B extending in the Y-direction in another lower conducting layer (e.g., the second backside metal layer BM1) through a corresponding via-connector BV0.

In the circuit cell 500, as shown in the lower portion of FIG. 5A, the switch-select conductor 165A extends in the X-direction between the node-connector 122A and the node-connector 124A, and the switch-select conductor 165B extends in the X-direction between the node-connector 122B and the node-connector 124B. Other layout arrangements of the switch-select conductor and the node-connectors are within the contemplated scope of the present disclosure. Some example variations of the layout arrangements are depicted in FIGS. 6A-6B, each of which specifies a lower portion of the layout diagram for the circuit cell 500.

In FIG. 6A, the node-connector 122A extends in the X-direction between the switch-select conductor 165A and the node-connector 124A, while the node-connector 122B extends in the X-direction between the switch-select conductor 165B and the node-connector 124B. In FIG. 6B, the node-connector 124A extends in the X-direction between the node-connector 122A and the switch-select conductor 165A, while the node-connector 124B extends in the X-direction between the node-connector 122B and the switch-select conductor 165B.

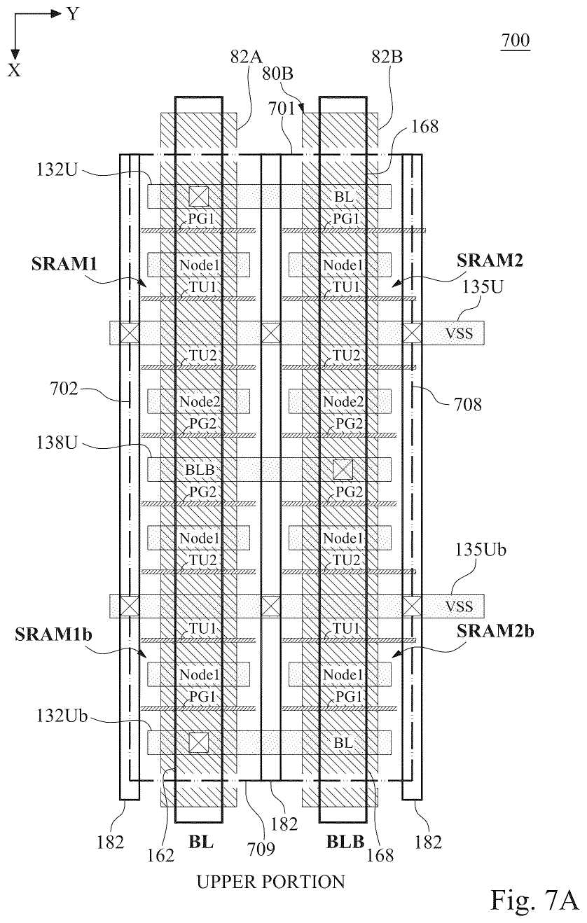

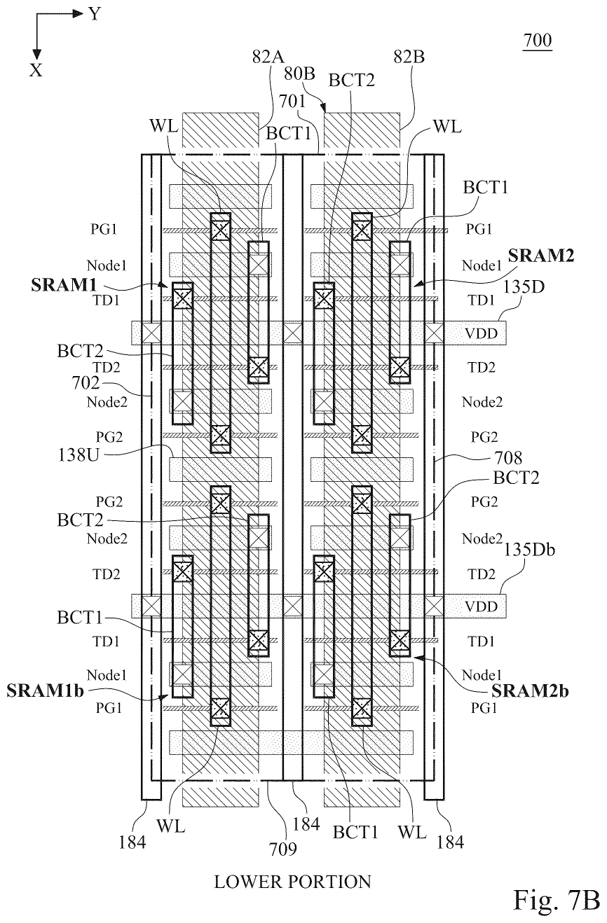

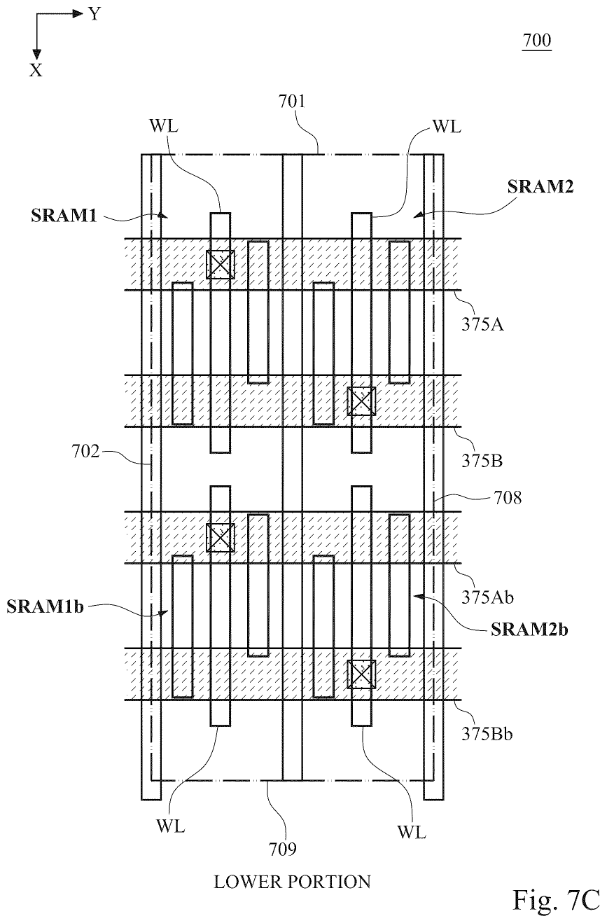

In FIG. 1A and FIG. 5A, each of the circuit cell 100 and the circuit cell 500 includes two SRAM bit-cell circuits: a first SRAM bit-cell circuit SRAM1 implemented with transistors in a first pair of stacked active-region structures (e.g., 80A) and a second SRAM bit-cell circuit SRAM2 implemented with transistors in a second pair of stacked active-region structures (e.g., 80B). In some alternative embodiments, the example circuit cell specified by the layout diagrams in FIGS. 7A-7B includes more than two SRAM bit-cell circuits.

FIGS. 7A-7B are correspondingly the upper portion and the lower portion of a layout diagram of a circuit cell 700 which has four SRAM circuits implemented with CFET devices, in accordance with some embodiments. In FIGS. 7A-7B, the circuit cell 700 is bounded by cell boundaries 701 and 709, each extending in the Y-direction and cell boundaries 702 and 708 each extending in the X-direction. Similar to the isolation regions at the cell boundaries 101 and 109 in FIG. 1A, the boundary isolation regions in the active-region structures at the cell boundaries 701 and 709 in FIGS. 7A-7B isolate the active regions of the transistors in the SRAM circuits of the circuit cell 700 from other active regions outside the circuit cell 700.

In FIGS. 7A-7B, the circuit cell 700 includes four SRAM bit-cell circuits: two SRAM bit-cell circuits SRAM1 and SRAM1b implemented with transistors in a first pair of stacked active-region structures 80A and two SRAM bit-cell circuits SRAM2 and SRAM2b implemented with transistors in a second pair of stacked active-region structures 80B. Similar to the SRAM bit-cell circuit SRAM1 and the SRAM bit-cell circuit SRAM2 in the circuit cell 500 of FIG. 5A, each of the SRAM bit-cell circuits SRAM1 and SRAM1b is implemented with two CFET devices (i.e., CFET1 and CFET2) and two switching transistors (i.e., PG1 and PG2) in the first pair of stacked active-region structures 80A, and each of the SRAM bit-cell circuits SRAM2 and SRAM2b is implemented with two CFET devices (i.e., CFET1 and CFET2) and two switching transistors (i.e., PG1 and PG2) in the second pair of stacked active-region structures 80B. Each CFET device CFET1 includes a first-type transistor TU1 and a second-type transistor TD1, and each CFET device CFET2 includes a first-type transistor TU2 and a second-type transistor TD2.

In each of the SRAM bit-cell circuits SRAM1, SRAM2, SRAM1b, and SRAM2b, as shown in FIG. 7B, the node-connector BCT1 conductively connects the drain terminal of the second-type transistor TD1 with the gate terminal of the second-type transistor TD2, while the node-connector BCT2 conductively connects the gate terminal of the second-type transistor TD1 with the drain terminal of the second-type transistor TD2. In addition, the switch-select conductor WL in each of the SRAM bit-cell circuits conductively connects the gate terminal of the switching transistor PG1 with the gate terminal of the switching transistor PG2.

In FIGS. 7A-7B, the SRAM bit-cell circuits SRAM1 and SRAM2 are implemented with transistors within a first half of the circuit cell 700 near the cell boundary 701. The SRAM bit-cell circuits SRAM1b and SRAM2b are implemented with transistors within a second half of the circuit cell 700 near the cell boundary 709.

In FIG. 7A, the terminal-conductor 135U (which functions as the source terminals for the first-type transistors TU1 and TU2 in both the SRAM bit-cell circuits SRAM1 and SRAM2) is connected to the three power-line conductors 182 through via-connectors. The terminal-conductor 135UB (which functions as the source terminals for the first-type transistors TU1 and TU2 in both the SRAM bit-cell circuits SRAM1b and SRAM2b ) is also connected to the three power-line conductors 182 through via-connectors.

In FIG. 7B, the terminal-conductor 135D (which functions as the source terminals for the second-type transistors TD1 and TD2 in both the SRAM bit-cell circuits SRAM1 and SRAM2) is connected to the three power-line conductors 184 through via-connectors. The terminal-conductor 135DB (which functions as the source terminals for the second-type transistors TD1 and TD2 in both the SRAM bit-cell circuits SRAM1b and SRAM2b ) is also connected to the three power-line conductors 184 through via-connectors.

In FIG. 7A, the terminal-conductor 132U (which functions as a source/drain terminal of the switching transistor PG1 in each of the SRAM bit-cell circuits SRAM1 and SRAM2 adjacent to the cell boundary 701) is conductively connected to the bit-line conductor 162 through a via-connector VD. The terminal-conductor 132Ub (which functions as a source/drain terminal of the switching transistor PG1 in each of the SRAM bit-cell circuits SRAM1b and SRAM2b adjacent to the cell boundary 709) is also conductively connected to the bit-line conductor 162 through a via-connector VD. Thus, the bit-line conductor 162 is conductively connected to the first bit-IO terminal-conductor BL for each of the SRAM bit-cell circuits SRAM1, SRAM2, SRAM1b, and SRAM2b.

Furthermore, in FIG. 7A, the terminal-conductor 138U (which functions as a source/drain terminal of the switching transistor PG2 in each of the SRAM bit-cell circuits SRAM1, SRAM2, SRAM1b, and SRAM2b ) is conductively connected to the bit-line conductor 168 through a via-connector VD. Thus, the bit-line conductor 168 is conductively connected to the second bit-IO terminal-conductor BLB for each of the SRAM bit-cell circuits SRAM1, SRAM2, SRAM1b, and SRAM2b.

In FIG. 7B, each switch-select conductor WL is implemented to select or deselect the corresponding bit-cell circuit for reading or writing. In operation, the voltage signals applied to the switch-select conductors WL determine which one of the four bit-cell circuits (i.e., SRAM1, SRAM2, SRAM1b, or SRAM2b ) is selected as a selected bit-cell circuit for reading or writing. The first connection node Node1 in the selected bit-cell circuit is conductively connected to the bit-line conductor 162, while the second connection node Node2 in the selected bit-cell circuit is conductively connected to the bit-line conductor 168. The connection nodes Node1 and Node2 in the remaining three unselected bit-cell circuits are decoupled from the bit-line conductors 162 and 168. The connections between the switch-select conductors WL and some of the word-lines passing across the circuit cell 700 are depicted in FIG. 7C.

FIG. 7C is a lower portion of the layout diagram of the circuit cell 700 which has layout patterns for specifying the word-lines connected to the switch-select conductors WL, in accordance with some embodiments. In some embodiments, the switch-select conductors WL (all extending in the X-direction) are fabricated in a first backside metal layer BM0 (which is below the CFETs in the integrated circuit) at a backside of the substrate. The word-lines 375A, 375B, 375Ab, and 375Bb (all extending in the Y-direction) are fabricated in a second backside metal layer BM1 below the first backside metal layer BM0. The switch-select conductors WL in the SRAM bit-cell circuits SRAM1, SRAM2, SRAM1b, and SRAM2b are correspondingly connected to the word-lines 375A, 375B, 375Ab, and 375Bb through a via-connector BV0.

In operation, a selecting voltage signal is applied to one of the four the word-lines 375A, 375B, 375Ab, and 375Bb, and deselecting voltage signals is applied to the remaining three of the word-lines. The SRAM bit-cell circuit which has the switch-select conductor WL thereof connected to the word-line having the selecting voltage signal becomes the selected bit-cell circuit for reading or writing.

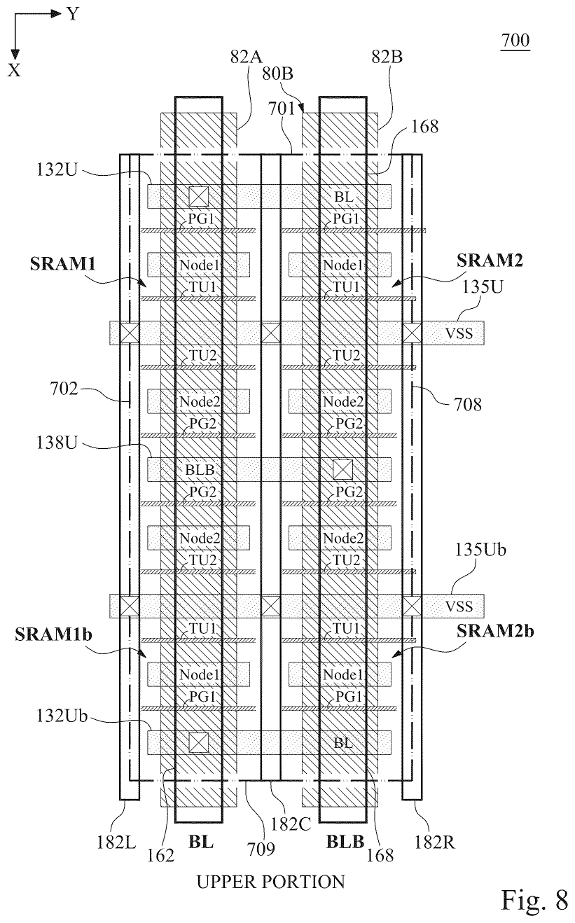

An alternative implementation of the integrated circuit in FIG. 7A is shown in FIG. 8. The integrated circuit as shown in FIG. 8 is modified from the integrated circuit in FIG. 7A by changing the position of the bit-line conductors 162 and 168 along the Y-direction. In FIG. 8, each of the bit-line conductors 162 and 168 extending in the X-direction is asymmetrically positioned between two power-line conductors. In some embodiments, a first distance along the Y-direction separating the bit-line conductor 162 from the power-line conductor 182L is at least two times as large as a second distance along the Y-direction separating the bit-line conductor 162 from the power-line conductor 182C. A first distance along the Y-direction separating the bit-line conductor 168 from the power-line conductor 182C is at least two times as large as a second distance along the Y-direction separating the bit-line conductor 168 from the power-line conductor 182R.

In some embodiments, the transistors in the circuit cell 100, 500, or 700 (correspondingly with layout designs as shown in FIG. 1A, FIG. 5A, and FIG. 7A) are not always implemented with the same threshold. In some amendments, the transistors TU1, TU2, TD1, and TD2 in each SRAM bit-cell circuit of a circuit cell (e.g., 100, 500, and 700) has a first threshold Vth1, while the transistors PG1 and PG2 in the same SRAM bit-cell circuit has a second threshold Vth2. In an integrated circuit formed with a matrix of circuit cells, with each circuit cell being implemented based on one of the presently disclosed layout designs (such as the layout designs in FIG. 1A, FIG. 5A, and FIG. 7A), transistors of a same threshold are grouped into a larger layout area, as compared with some existing layout designs.

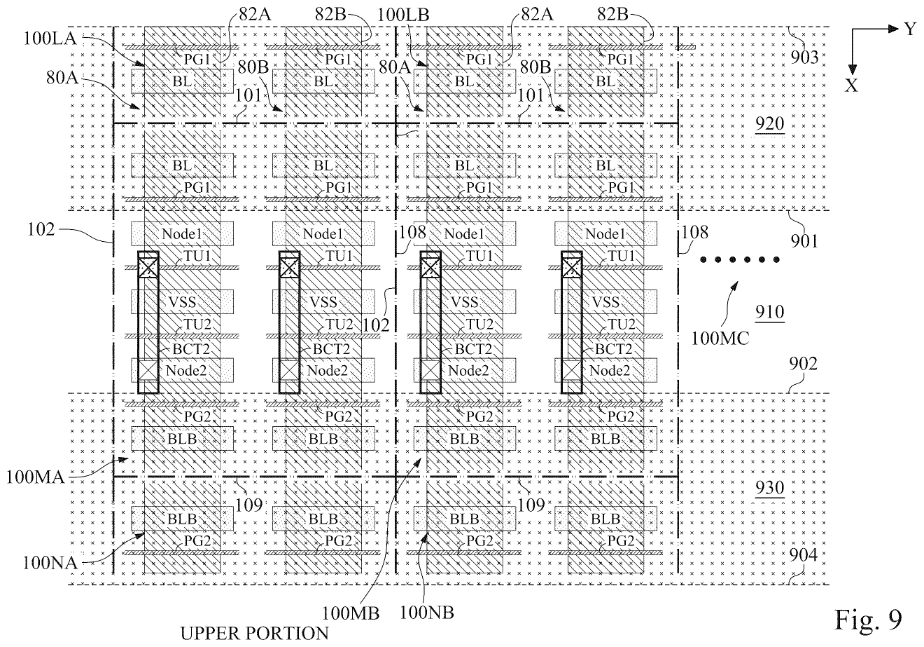

FIG. 9 is a schematic of some portions of a matrix of circuit cells, in accordance with some embodiments. In one example, the matrix of circuit cells in FIG. 9 are formed with circuit cells as shown in FIG. 1B. The circuit cells in FIG. 9 arranged in multiple rows (along the Y-direction). Three rows (i.e., rows L, M, and N) of the circuit cells are schematically identified in FIG. 9. Two circuit cells 100MA and 100MB of the row M are shown in more detail, but the remaining circuit cells (such as 100MC et al.) of the row M are not explicitly shown. Only the transistors PG1 in selected circuit cells (i.e., 100LA and 100LB) of the row L are depicted, and only the transistors PG2 in selected circuit cells (i.e., 100NA and 100NB) of the row N are depicted. The transistors in the layout area 910 (between borderlines 901 and 902 extending in the Y-direction) are fabricated with a first threshold Vth1. The transistors in the layout area 910 include the transistors TU1, TU2, TD1, and TD2 in each SRAM bit-cell circuit of the circuit cells of the row M (note here that transistors TD1 and TD2 are not explicitly shown in FIG. 9). The transistors in the layout area 920 (between borderlines 901 and 903 extending in the Y-direction) are fabricated with a second threshold Vth2, and the transistors in the layout area 920 include the transistors PG1 in each SRAM bit-cell circuit of the circuit cells of the row M. The transistors in the layout area 930 (between borderlines 903 and 904 extending in the Y-direction) are fabricated with a second threshold Vth2, and the transistors in the layout area 930 include the transistors PG2 in each SRAM bit-cell circuit of the circuit cells of the row N.

In some embodiments, each layout area (910, 920, or 930) of a single threshold is defined by one or more masks during device fabrications. As each layout area (910, 920, or 930) of a single threshold forming a strip parallel to the rows of the matrix along the Y-direction, the layout designs of the circuit cell 100, 500, and 700 (correspondingly in FIG. 1A, FIG. 5A, and FIG. 7A) enable a more friendly fabrication process for defining single-threshold layout areas, as compared with some existing layout designs in which single-threshold layout areas are interlaced with each other in checkboard patterns.

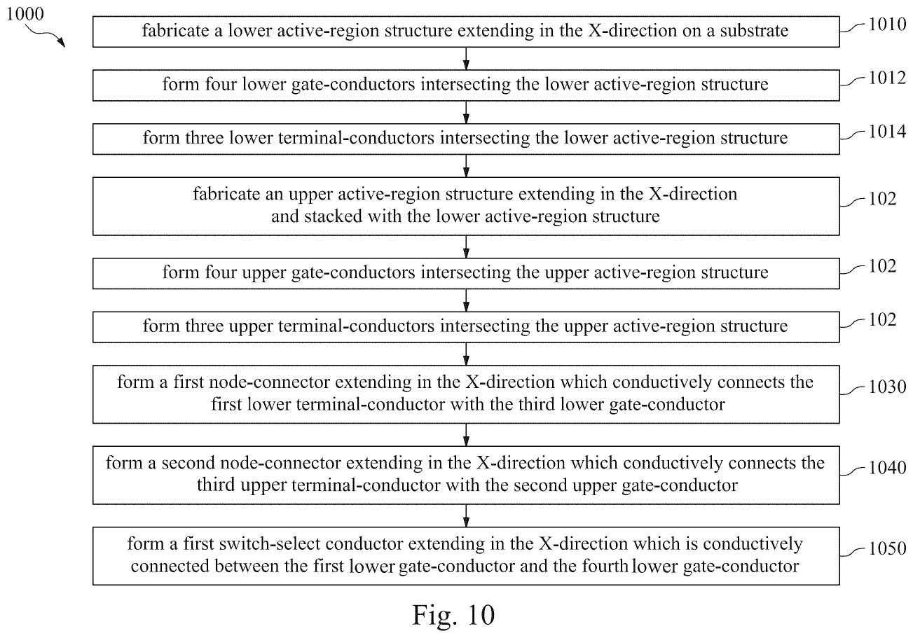

FIG. 10 is a flowchart of a method 1000 of manufacturing an integrated circuit (IC) having CFET devices, in accordance with some embodiments. It is understood that additional operations may be performed before, during, and/or after the method 1000 depicted in FIG. 10, and that some other processes may only be briefly described herein.

In operation 1010 of the method 1000, a lower active-region structure extending in the X-direction is fabricated on a substrate. In the example embodiments as shown in FIGS. 1A-1B and FIGS. 2A-2C, the lower active-region structures 84A is fabricated on the substrate 30.

In operation 1012 of the method 1000, four lower gate-conductors are formed intersecting the lower active-region structure. In the example embodiments as shown in FIGS. 1A-1B and FIGS. 2A-2C, the gate-conductors 152DA and 158DA and the lower parts of the gate-conductors 154A and 156A are formed intersecting the lower active-region structure 84A.

In operation 1014 of the method 1000, three lower terminal-conductors are formed intersecting the lower active-region structure. In the example embodiments as shown in FIGS. 1A-1B and FIGS. 2A-2C, the terminal-conductor 135DA and the lower parts of the terminal-conductors 134A and 136A are formed intersecting the lower active-region structure 84A.

In operation 1020 of the method 1000, an upper active-region structure extending in the X-direction is fabricated and the upper active-region structure is stacked with the lower active-region structure. In the example embodiments as shown in FIGS. 1A-1B and FIGS. 2A-2C, the upper active-region structure 82A is fabricated, and the upper active-region structures 82A is stacked with the lower active-region structure 84A.

In operation 1022 of the method 1000, four upper gate-conductors are formed intersecting the upper active-region structure. In the example embodiments as shown in FIGS. 1A-1B and FIGS. 2A-2C, the gate-conductors 152UA and 158UA and the upper parts of the gate-conductors 154A and 156A are formed intersecting the upper active-region structure 82A.

In operation 1024 of the method 1000, three upper terminal-conductors are formed intersecting the upper active-region structure. In the example embodiments as shown in FIGS. 1A-1B and FIGS. 2A-2C, the terminal-conductor 135UA and the upper parts of the terminal-conductors 134A and 136A are formed intersecting the upper active-region structure 82A.

In operation 1030 of the method 1000, a first node-connector extending in the X-direction is formed in a lower conducting layer, and the first node-connector conductively connects the first lower terminal-conductor with the third lower gate-conductor. In the example embodiments as shown in FIGS. 1A-1B and FIGS. 2A-2C, the node-connector 124A is formed in a lower conducting layer, and the node-connector 124A conductively connects the lower part of the terminal-conductor 134A with the lower part of the gate-conductor 156A.

In operation 1040 of the method 1000, a second node-connector extending in the X-direction is formed in an upper conducting layer, and the second node-connector conductively connects the third upper terminal-conductor with the second upper gate-conductor. In the example embodiments as shown in FIGS. 1A-1B and FIGS. 2A-2C, the node-connector 122A is formed in the frontside metal layer M0, and the node-connector 122A conductively connects the upper part of the terminal-conductor 136A with the upper part of the gate-conductor 154A.

In operation 1050 of the method 1000, a first switch-select conductor extending in the X-direction is formed, and the first switch-select conductor is conductively connected between the first lower gate-conductor and the fourth lower gate-conductor. In the example embodiments as shown in FIGS. 1A-1B and FIGS. 2A-2C, the switch-select conductor 165A is formed in the backside metal layer BM0, and the switch-select conductor 165A is conductively connected between the gate-conductor 152DA and the gate-conductor 158DA.

In some alternative embodiments, in operation 1040 of the method 1000, a second node-connector extending in the X-direction is formed in a lower conducting layer, and the second node-connector conductively connects the third lower terminal-conductor with the second lower gate-conductor. In the example embodiments as shown in FIG. 5A, the node-connector 122A is formed in the backside metal layer BM0, and the node-connector 122A conductively connects the lower part of the terminal-conductor 136A with the lower part of the gate-conductor 154A.

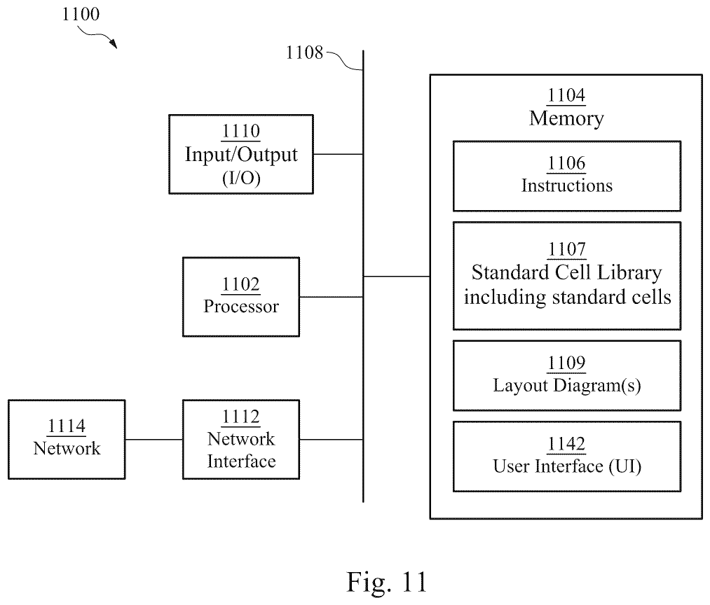

FIG. 11 is a block diagram of an electronic design automation (EDA) system 1100 in accordance with some embodiments.

In some embodiments, EDA system 1100 includes an automatic placement and routing (APR) system. Methods described herein of designing layout diagrams represent wire routing arrangements, in accordance with one or more embodiments, are implementable, for example, using EDA system 1100, in accordance with some embodiments.

In some embodiments, EDA system 1100 is a general purpose computing device including a hardware processor 1102 and a non-transitory, computer-readable storage medium 1104. Storage medium 1104, amongst other things, is encoded with, i.e., stores, computer program code 1106, i.e., a set of executable instructions. Execution of instructions 1106 by hardware processor 1102 represents (at least in part) an EDA tool which implements a portion or all of the methods described herein in accordance with one or more embodiments (hereinafter, the noted processes and/or methods).

Processor 1102 is electrically coupled to computer-readable storage medium 1104 via a bus 1108. Processor 1102 is also electrically coupled to an I/O interface 1110 by bus 1108. A network interface 1112 is also electrically connected to processor 1102 via bus 1108. Network interface 1112 is connected to a network 1114, so that processor 1102 and computer-readable storage medium 1104 are capable of connecting to external elements via network 1114. Processor 1102 is configured to execute computer program code 1106 encoded in computer-readable storage medium 1104 in order to cause system 1100 to be usable for performing a portion or all of the noted processes and/or methods. In one or more embodiments, processor 1102 is a central processing unit (CPU), a multi-processor, a distributed processing system, an application specific integrated circuit (ASIC), and/or a suitable processing unit.

In one or more embodiments, computer-readable storage medium 1104 is an electronic, magnetic, optical, electromagnetic, infrared, and/or a semiconductor system (or apparatus or device). For example, computer-readable storage medium 1104 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1104 includes a compact disk-read only memory (CD-ROM), a compact disk-read/write (CD-R/W), and/or a digital video disc (DVD).

In one or more embodiments, storage medium 1104 stores computer program code 1106 configured to cause system 1100 (where such execution represents (at least in part) the EDA tool) to be usable for performing a portion or all of the noted processes and/or methods. In one or more embodiments, storage medium 1104 also stores information which facilitates performing a portion or all of the noted processes and/or methods. In one or more embodiments, storage medium 1104 stores library 1107 of standard cells including such standard cells as disclosed herein. In one or more embodiments, storage medium 1104 stores one or more layout diagrams 1109 corresponding to one or more layouts disclosed herein.

EDA system 1100 includes I/O interface 1110. I/O interface 1110 is coupled to external circuitry. In one or more embodiments, I/O interface 1110 includes a keyboard, keypad, mouse, trackball, trackpad, touchscreen, and/or cursor direction keys for communicating information and commands to processor 1102.

EDA system 1100 also includes network interface 1112 coupled to processor 1102. Network interface 1112 allows system 1100 to communicate with network 1114, to which one or more other computer systems are connected. Network interface 1112 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1100.

System 1100 is configured to receive information through I/O interface 1110. The information received through I/O interface 1110 includes one or more of instructions, data, design rules, libraries of standard cells, and/or other parameters for processing by processor 1102. The information is transferred to processor 1102 via bus 1108. EDA system 1100 is configured to receive information related to a user interface (UI) through I/O interface 1110. The information is stored in computer-readable medium 1104 as UI 1142.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1100. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

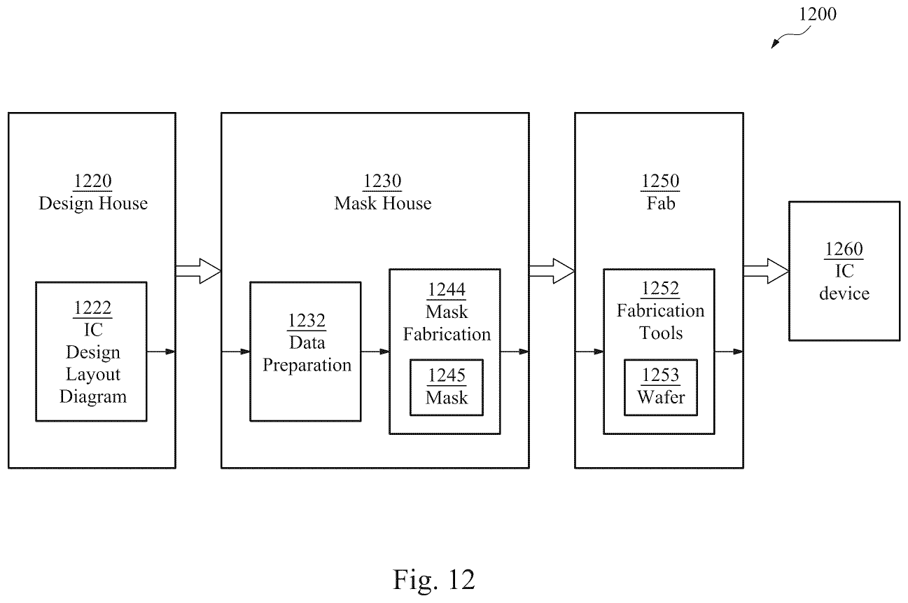

FIG. 12 is a block diagram of an integrated circuit (IC) manufacturing system 1200, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1200.

In FIG. 12, IC manufacturing system 1200 includes entities, such as a design house 1220, a mask house 1230, and an IC manufacturer/fabricator (fab) 1250, that interact with one another in the design, development, and manufacturing cycles and/or services related to manufacturing an IC device 1260. The entities in system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1220, mask house 1230, and IC fab 1250 is owned by a single larger company. In some embodiments, two or more of design house 1220, mask house 1230, and IC fab 1250 coexist in a common facility and use common resources.

Design house (or design team) 1220 generates an IC design layout diagram 1222. IC design layout diagram 1222 includes various geometrical patterns designed for an IC device 1260. The geometrical patterns correspond to patterns of metal, oxide, or semiconductor layers that make up the various components of IC device 1260 to be fabricated. The various layers combine to form various IC features. For example, a portion of IC design layout diagram 1222 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1220 implements a proper design procedure to form IC design layout diagram 1222. The design procedure includes one or more of logic design, physical design or place and route. IC design layout diagram 1222 is presented in one or more data files having information of the geometrical patterns. For example, IC design layout diagram 1222 can be expressed in a GDSII file format or DFII file format.

Mask house 1230 includes data preparation 1232 and mask fabrication 1244. Mask house 1230 uses IC design layout diagram 1222 to manufacture one or more masks 1245 to be used for fabricating the various layers of IC device 1260 according to IC design layout diagram 1222. Mask house 1230 performs mask data preparation 1232, where IC design layout diagram 1222 is translated into a representative data file (RDF). Mask data preparation 1232 provides the RDF to mask fabrication 1244. Mask fabrication 1244 includes a mask writer. A mask writer converts the RDF to an image on a substrate, such as a mask (reticle) 1245 or a semiconductor wafer 1253. The design layout diagram 1222 is manipulated by mask data preparation 1232 to comply with particular characteristics of the mask writer and/or requirements of IC fab 1250. In FIG. 12, mask data preparation 1232 and mask fabrication 1244 are illustrated as separate elements. In some embodiments, mask data preparation 1232 and mask fabrication 1244 can be collectively referred to as mask data preparation.

In some embodiments, mask data preparation 1232 includes optical proximity correction (OPC) which uses lithography enhancement techniques to compensate for image errors, such as those that can arise from diffraction, interference, other process effects and the like. OPC adjusts IC design layout diagram 1222. In some embodiments, mask data preparation 1232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1232 includes a mask rule checker (MRC) that checks the IC design layout diagram 1222 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1222 to compensate for photolithographic implementation effects during mask fabrication 1244, which may undo part of the modifications performed by OPC in order to meet mask creation rules.

In some embodiments, mask data preparation 1232 includes lithography process checking (LPC) that simulates processing that will be implemented by IC fab 1250 to fabricate IC device 1260. LPC simulates this processing based on IC design layout diagram 1222 to create a simulated manufactured device, such as IC device 1260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1222.

It should be understood that the above description of mask data preparation 1232 has been simplified for the purposes of clarity. In some embodiments, data preparation 1232 includes additional features such as a logic operation (LOP) to modify the IC design layout diagram 1222 according to manufacturing rules. Additionally, the processes applied to IC design layout diagram 1222 during data preparation 1232 may be executed in a variety of different orders.

After mask data preparation 1232 and during mask fabrication 1244, a mask 1245 or a group of masks 1245 are fabricated based on the modified IC design layout diagram 1222. In some embodiments, mask fabrication 1244 includes performing one or more lithographic exposures based on IC design layout diagram 1222. In some embodiments, an electron-beam (e-beam) or a mechanism of multiple e-beams is used to form a pattern on a mask (photomask or reticle) 1245 based on the modified IC design layout diagram 1222. Mask 1245 can be formed in various technologies. In some embodiments, mask 1245 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1245 includes a transparent substrate (e.g., fused quartz) and an opaque material (e.g., chromium) coated in the opaque regions of the binary mask. In another example, mask 1245 is formed using a phase shift technology. In a phase shift mask (PSM) version of mask 1245, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1244 is used in a variety of processes. For example, such a mask(s) is used in an ion implantation process to form various doped regions in semiconductor wafer 1253, in an etching process to form various etching regions in semiconductor wafer 1253, and/or in other suitable processes.

IC fab 1250 is an IC fabrication business that includes one or more manufacturing facilities for the fabrication of a variety of different IC products. In some embodiments, IC Fab 1250 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1250 includes fabrication tools 1252 configured to execute various manufacturing operations on semiconductor wafer 1253 such that IC device 1260 is fabricated in accordance with the mask(s), e.g., mask 1245. In various embodiments, fabrication tools 1252 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1250 uses mask(s) 1245 fabricated by mask house 1230 to fabricate IC device 1260. Thus, IC fab 1250 at least indirectly uses IC design layout diagram 1222 to fabricate IC device 1260. In some embodiments, semiconductor wafer 1253 is fabricated by IC fab 1250 using mask(s) 1245 to form IC device 1260. In some embodiments, the IC fabrication includes performing one or more lithographic exposures based at least indirectly on IC design layout diagram 1222. Semiconductor wafer 1253 includes a silicon substrate or other proper substrate having material layers formed thereon. Semiconductor wafer 1253 further includes one or more of various doped regions, dielectric features, multilevel interconnects, and the like (formed at subsequent manufacturing steps).

An aspect of the present disclosure relates to an integrated circuit device having CFET devices (complementary field effect transistor devices) therein. The integrated circuit device includes a first pair of stacked active-region structures extending in a first direction and passing across four gate tracks extending in a second direction, where the four gate tracks are distributed evenly along the first direction in an order of a first gate track, a second gate track, a third gate track, and a fourth gate track; a first switching gate-conductor aligned with the first gate track and intersecting the first pair of stacked active-region structures as a gate of a first switching transistor, a first CFET gate-conductor aligned with the second gate track and intersecting the first pair of stacked active-region structures as a joined gate of a first CFET device, a second CFET gate-conductor aligned with the third gate track and intersecting the first pair of stacked active-region structures as a joined gate of a second CFET device, a second switching gate-conductor aligned with the fourth gate track and intersecting the first pair of stacked active-region structures as a gate of a second switching transistor. The device also includes a first CFET terminal-conductor intersecting the first pair of stacked active-region structures between the first gate track and the second gate track as a joint drain terminal of the first CFET device, where the first CFET terminal-conductor is conductively connected to the second CFET gate-conductor. The device also includes a second CFET terminal-conductor intersecting the first pair of stacked active-region structures between the third gate track and the fourth gate track as a joint drain terminal of the second CFET device, where the second CFET terminal-conductor is conductively connected to the first CFET gate-conductor.

Another aspect of the present disclosure relates to an integrated circuit device having CFET devices (complementary field effect transistor devices) therein. The integrated circuit device includes a first pair of stacked active-region structures and a second pair of stacked active-region extending in a first direction and crossing passing across four gate tracks extending in a second direction, where the four gate tracks are distributed evenly along the first direction in an order of a first gate track, a second gate track, a third gate track, and a fourth gate track; a first switching gate-conductor, a first CFET gate-conductor, a second CFET gate-conductor, and a second switching gate-conductor all intersecting the first pair of stacked active-region structures; and a third switching gate-conductor, a third CFET gate-conductor, a fourth CFET gate-conductor, and a fourth switching gate-conductor all intersecting second pair of stacked active-region structures, and where the first switching gate-conductor and the third switching gate-conductor are aligned with the first gate track, the first CFET gate-conductor and the third CFET gate-conductor are aligned with the second gate track, the second CFET gate-conductor and the fourth CFET gate-conductor are aligned with the third gate track, and the second switching gate-conductor and the fourth switching gate-conductor are aligned with the fourth gate track. The device also includes a first CFET terminal-conductor intersecting the first pair of stacked active-region structures between the first gate track and the second gate track as a joint drain terminal of a first CFET device, where the first CFET terminal-conductor is conductively connected to the second CFET gate-conductor. The device also includes a second CFET terminal-conductor intersecting the first pair of stacked active-region structures between the third gate track and the fourth gate track as a joint drain terminal of a second CFET device, where the second CFET terminal-conductor is conductively connected to the first CFET gate-conductor.

Still another aspect of the present disclosure relates to a method. The method includes fabricating a lower active-region structure extending in a first direction on a substrate. The method also includes forming four lower gate-conductors intersecting the lower active-region structure, where the four lower gate-conductors includes a second lower gate-conductor and a third gate-conductor between a first lower gate-conductor and a fourth lower gate-conductor. The method also includes forming three lower terminal-conductors intersecting the lower active-region structure, where the three lower terminal-conductors includes a first lower terminal-conductor between the first and the second lower gate-conductors, a second lower terminal-conductor between the second and the third lower gate-conductors, and a third lower terminal-conductor between the third and the fourth lower gate-conductors, and where the second lower terminal-conductor is between the first and the third lower terminal-conductor. The method also includes fabricating an upper active-region structure extending in the first direction and stacked with the lower active-region structure. The method also includes forming four upper gate-conductors intersecting the upper active-region structure, where the four upper gate-conductors includes a second upper gate-conductor and a third upper gate-conductor between a first upper gate-conductor and a fourth upper gate-conductor, and where the second upper gate-conductor is stacked with and conductively connected to the second lower gate-conductor and the third upper gate-conductor is stacked with and conductively connected to the third lower gate-conductor. The method also includes forming three upper terminal-conductors intersecting the upper active-region structure, where the three upper terminal-conductors includes a first upper terminal-conductor stacked with and conductively connected to the first lower terminal-conductor, a second upper terminal-conductor stacked with the second lower terminal-conductor, and a third upper terminal-conductor stacked with and conductively connected to the third lower terminal-conductor. The method also includes forming a first node-connector extending in the first direction which conductively connects one of the first upper terminal-conductor and the first lower terminal-conductor with one of the third upper gate-conductor and the third lower gate-conductor. The method also includes forming a second node-connector extending in the first direction which conductively connects one of the third upper terminal-conductor and the third lower terminal-conductor with one of the second upper gate-conductor and the second lower gate-conductor.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

1. An integrated circuit device comprising:
a first pair of stacked active-region structures extending in a first direction and passing across four gate tracks extending in a second direction, wherein the four gate tracks are distributed evenly along the first direction in an order of a first gate track, a second gate track, a third gate track, and a fourth gate track;
a first switching gate-conductor aligned with the first gate track and intersecting the first pair of stacked active-region structures as a gate of a first switching transistor;
a first CFET gate-conductor aligned with the second gate track and intersecting the first pair of stacked active-region structures as a joined gate of a first CFET device;
a second CFET gate-conductor aligned with the third gate track and intersecting the first pair of stacked active-region structures as a joined gate of a second CFET device;
a second switching gate-conductor aligned with the fourth gate track and intersecting the first pair of stacked active-region structures as a gate of a second switching transistor;
a first CFET terminal-conductor intersecting the first pair of stacked active-region structures between the first gate track and the second gate track as a joint drain terminal of the first CFET device, wherein the first CFET terminal-conductor is conductively connected to the second CFET gate-conductor; and
a second CFET terminal-conductor intersecting the first pair of stacked active-region structures between the third gate track and the fourth gate track as a joint drain terminal of the second CFET device, wherein the second CFET terminal-conductor is conductively connected to the first CFET gate-conductor.

2. The integrated circuit device of claim 1, further comprising:
a first node-connector extending in the first direction which connects the first CFET terminal-conductor with the second CFET gate-conductor while non-conductively passing across the first CFET gate-conductor; and
a second node-connector extending in the first direction which connects the second CFET terminal-conductor with the first CFET gate-conductor while non-conductively passing across the second CFET gate-conductor.

3. The integrated circuit device of claim 1, further comprising:
a first switch-select conductor extending in the first direction which conductively connects the first switching gate-conductor with the second switching gate-conductor; and
a first word-line extending in the second direction and conductively connected to the first switch-select conductor.

4. The integrated circuit device of claim 1, further comprising:
a first bit-IO (“input-output”) terminal-conductor intersecting the first pair of stacked active-region structures at a terminal region of the first switching transistor, wherein the first switching gate-conductor is between the first bit-IO terminal-conductor and the first CFET terminal-conductor; and
a second bit-IO terminal-conductor intersecting the first pair of stacked active-region structures at a terminal region of the second switching transistor, wherein the second switching gate-conductor is between the second bit-IO terminal-conductor and the second CFET terminal-conductor.

5. The integrated circuit device of claim 1, wherein:
the first pair of stacked active-region structures includes an upper active-region structure and a lower active-region structure stacked with each other along a normal direction of a substrate, and the lower active-region structure is between the upper active-region structure and the substrate.

6. The integrated circuit device of claim 5, wherein:
the first switching gate-conductor intersects either the upper active-region structure or the lower active-region structure at a channel region of the first switching transistor; and
the second switching gate-conductor intersects either the upper active-region structure or the lower active-region structure at the channel region of the second switching transistor.

7. The integrated circuit device of claim 5, further comprising:
a first power terminal-conductor intersecting the upper active-region structure between the second gate track and the third gate track;
a second power terminal-conductor intersecting the lower active-region structure between the second gate track and the third gate track; and
a first power-line conductor extending in the first direction and conductively connected to either the first power terminal-conductor or the second power terminal-conductor.

8. The integrated circuit device of claim 7, further comprising:
a first bit-IO terminal-conductor intersecting the first pair of stacked active-region structures at a terminal region of the first switching transistor which is coupled to the first CFET terminal-conductor through a channel of the first switching transistor;
a first bit-line conductor extending in the first direction which is conductively connected to the first bit-IO terminal-conductor;
a second bit-IO terminal-conductor intersecting the first pair of stacked active-region structures at a terminal region of the second switching transistor which is coupled to the second CFET terminal-conductor through a channel of the second switching transistor; and
a second bit-line conductor extending in the first direction which is conductively connected to the second bit-IO terminal-conductor, and wherein the first power-line conductor extends in the first direction parallelly between the first bit-line conductor and the second bit-line conductor in a same conducting layer.

9. The integrated circuit device of claim 8, further comprising:
a second power-line conductor extending in the first direction and conductively connected to either the first power terminal-conductor or the second power terminal-conductor; and
a third power-line conductor extending in the first direction and conductively connected to either the first power terminal-conductor or the second power terminal-conductor, and wherein the first bit-line conductor and the second bit-line conductor extend in the first direction parallelly between the second power-line conductor and the third power-line conductor in a same conducting layer.

10. The integrated circuit device of claim 5, wherein:
the first CFET gate-conductor includes a first upper gate-conductor and a first lower gate-conductor which are conductively connected and stacked with each other along the normal direction of the substrate, the first upper gate-conductor intersects the upper active-region structure, and the first lower gate-conductor intersecting the lower active-region structure;
the second CFET gate-conductor includes a second upper gate-conductor and a second lower gate-conductor which are conductively connected and stacked with each other along the normal direction of the substrate, the second upper gate-conductor intersects the upper active-region structure, and the second lower gate-conductor intersecting the lower active-region structure;
the first CFET terminal-conductor includes both a first upper terminal-conductor and a first lower terminal-conductor which are conductively connected and stacked with each other along the normal direction of the substrate, the first upper terminal-conductor intersects the upper active-region structure, and the first lower terminal-conductor intersecting the lower active-region structure; and
the second CFET terminal-conductor includes both a second upper terminal-conductor and a second lower terminal-conductor which are conductively connected and stacked with each other along the normal direction of the substrate, the second upper terminal-conductor intersects the upper active-region structure, and the second lower terminal-conductor intersecting the lower active-region structure.

11. The integrated circuit device of claim 10, further comprising:
a first node-connector, in an upper conducting layer above the upper active-region structure, which connects the first upper terminal-conductor with the second upper gate-conductor through via-connectors; and
a second node-connector, in a lower conducting layer below the lower active-region structure, which connects the second lower terminal-conductor with the first lower gate-conductor through via-connectors.

12. The integrated circuit device of claim 10, further comprising:
a first node-connector, in a lower conducting layer below the lower active-region structure, which connects the first lower terminal-conductor with the second lower gate-conductor through via-connectors; and
a second node-connector, in a lower conducting layer below the lower active-region structure, which connects the second lower terminal-conductor with the first lower gate-conductor through via-connectors.

13. The integrated circuit device of claim 10, further comprising:
a first node-connector, in an upper conducting layer above the upper active-region structure, which connects the first upper terminal-conductor with the second upper gate-conductor through via-connectors; and
a second node-connector, in an upper conducting layer above the upper active-region structure, which connects the second upper terminal-conductor with the first upper gate-conductor through via-connectors.

14. An integrated circuit device comprising:
a first pair of stacked active-region structures and a second pair of stacked active-region structures extending in a first direction and crossing passing across four gate tracks extending in a second direction, wherein the four gate tracks are distributed evenly along the first direction in an order of a first gate track, a second gate track, a third gate track, and a fourth gate track;
a first switching gate-conductor, a first CFET gate-conductor, a second CFET gate-conductor, and a second switching gate-conductor all intersecting the first pair of stacked active-region structures;
a third switching gate-conductor, a third CFET gate-conductor, a fourth CFET gate-conductor, and a fourth switching gate-conductor all intersecting second pair of stacked active-region structures, and wherein the first switching gate-conductor and the third switching gate-conductor are aligned with the first gate track, the first CFET gate-conductor and the third CFET gate-conductor are aligned with the second gate track, the second CFET gate-conductor and the fourth CFET gate-conductor are aligned with the third gate track, and the second switching gate-conductor and the fourth switching gate-conductor are aligned with the fourth gate track;
a first CFET terminal-conductor intersecting the first pair of stacked active-region structures between the first gate track and the second gate track as a joint drain terminal of a first CFET device, wherein the first CFET terminal-conductor is conductively connected to the second CFET gate-conductor; and
a second CFET terminal-conductor intersecting the first pair of stacked active-region structures between the third gate track and the fourth gate track as a joint drain terminal of a second CFET device, wherein the second CFET terminal-conductor is conductively connected to the first CFET gate-conductor.

15. The integrated circuit device of claim 14, further comprising:
a third CFET terminal-conductor intersecting the second pair of stacked active-region structures between the first gate track and the second gate track as a joint drain terminal of a third CFET device, wherein the third CFET terminal-conductor is conductively connected to the fourth CFET gate-conductor; and
a fourth CFET terminal-conductor intersecting the second pair of stacked active-region structures between the third gate track and the fourth gate track as a joint drain terminal of a fourth CFET device, wherein the fourth CFET terminal-conductor is conductively connected to the third CFET gate-conductor.

16. The integrated circuit device of claim 14, further comprising:
a first switch-select conductor extending in the first direction which is conductively connected between the first switching gate-conductor and the second switching gate-conductor;
a first word-line extending in the second direction and conductively connected to the first switch-select conductor;
a second switch-select conductor extending in the first direction which is conductively connected between the third switching gate-conductor and the fourth switching gate-conductor; and
a second word-line extending in the second direction and conductively connected to the second switch-select conductor.

17. The integrated circuit device of claim 14, further comprising:
a first bit-IO (“input-output”) terminal-conductor and a second bit-IO terminal-conductor extending in the second direction, in a configuration such that the four gate tracks are between the first bit-IO terminal-conductor and the second bit-IO terminal-conductor, wherein each of the first bit-IO terminal-conductor and the second bit-IO terminal-conductor intersects both the first pair of stacked active-region structures and the second pair of stacked active-region structures; and
a first power terminal-conductor extending in the second direction between the second gate track and the third gate track, wherein the first power terminal-conductor intersects one or both of the first pair of stacked active-region structures or the second pair of stacked active-region structures.

18. The integrated circuit device of claim 17, further comprising:
a first bit-line conductor extending in the first direction which is conductively connected to the first bit-IO terminal-conductor;
a second bit-line conductor extending in the first direction which is conductively connected to the second bit-IO terminal-conductor; and
a first power-line conductor extending in the first direction parallelly between the first bit-line conductor and the second bit-line conductor, wherein the first power-line conductor is conductively connected to the first power terminal-conductor.

19. A method comprising:
fabricating a lower active-region structure extending in a first direction on a substrate;
forming four lower gate-conductors intersecting the lower active-region structure, wherein the four lower gate-conductors include a second lower gate-conductor and a third lower gate-conductor between a first lower gate-conductor and a fourth lower gate-conductor;
forming three lower terminal-conductors intersecting the lower active-region structure, wherein the three lower terminal-conductors includes a first lower terminal-conductor between the first and the second lower gate-conductors, a second lower terminal-conductor between the second and the third lower gate-conductors, and a third lower terminal-conductor between the third and the fourth lower gate-conductors, and wherein the second lower terminal-conductor is between the first and the third lower terminal-conductor;
fabricating an upper active-region structure extending in the first direction and stacked with the lower active-region structure;
forming four upper gate-conductors intersecting the upper active-region structure, wherein the four upper gate-conductors includes a second upper gate-conductor and a third upper gate-conductor between a first upper gate-conductor and a fourth upper gate-conductor, and wherein the second upper gate-conductor is stacked with and conductively connected to the second lower gate-conductor and the third upper gate-conductor is stacked with and conductively connected to the third lower gate-conductor;
forming three upper terminal-conductors intersecting the upper active-region structure, wherein the three upper terminal-conductors includes a first upper terminal-conductor stacked with and conductively connected to the first lower terminal-conductor, a second upper terminal-conductor stacked with the second lower terminal-conductor, and a third upper terminal-conductor stacked with and conductively connected to the third lower terminal-conductor;
forming a first node-connector extending in the first direction which conductively connects one of the first upper terminal-conductor and the first lower terminal-conductor with one of the third upper gate-conductor and the third lower gate-conductor; and
forming a second node-connector extending in the first direction which conductively connects one of the third upper terminal-conductor and the third lower terminal-conductor with one of the second upper gate-conductor and the second lower gate-conductor.

20. The method of claim 19, further comprising:
forming a first switch-select conductor extending in the first direction which is conductively connected between the first lower gate-conductor and the fourth lower gate-conductor or connected between the first upper gate-conductor and the fourth upper gate-conductor.
